(19) United States
(12) Patent Application Publication
(10) Pub. No.: US 2012/0073607 A1
(43) Pub. Date: Mar. 29, 2012

(54) POLYMERIC OR MONOMERIC COMPOSITIONS COMPRISING AT LEAST ONE MONO-AMIDE AND/OR AT LEAST ONE DIAMIDE FOR REMOVING SUBSTANCES FROM SUBSTRATES AND METHODS FOR USING THE SAME

(75) Inventors: Michael Wayne Quillen, Kingsport, TN (US); Dale Edward O'Dell, Blountville, TN (US); Zachary Philip Lee, Covington, GA (US); John Cleaon Moore, Camarillo, CA (US); Edward Enns McEntire, Kingsport, TN (US); Spencer Erich Hochstetler, Kingsport, TN (US)

(73) Assignee: Eastman Chemical Company

(21) Appl. No.: 12/891,698

(22) Filed: Sep. 27, 2010

(51) Int. Cl. B08B 3/00; G03F 7/42

(52) U.S. Cl. 134/19; 510/176

(57) ABSTRACT

Compositions and methods useful for removing organic substances from substrates, for example, electronic device substrates such as microelectronic wafers or flat panel displays, are provided. Methods are presented that apply a minimum volume of a composition as a coating to the inorganic substrate whereby sufficient heat is added and immediately rinsed with water to achieve complete removal. The compositions and methods may be suitable for removing and completely dissolving photoresists of the positive and negative varieties as well as thermoset polymers from electronic devices.

### CROSS-REFERENCE TO RELATED APPLICATIONS

This application claims priority to U.S. patent application Ser. No. 12/413,085, filed Mar. 27, 2009, and U.S. patent application Ser. No. 12/715,978, filed Mar. 2, 2010, which claims benefit of U.S. Provisional Patent Application No. 61/164,195 filed Mar. 27, 2009, the disclosures of which are incorporated herein by reference in their entirety.

### FIELD OF THE DISCLOSURE

The present disclosure relates generally to the removal of at least one substance from a substrate. In particular, the present disclosure relates to a method for use with a range of compositions, which may apply to the removal of both amorphous and thermoset polymers from electronic devices including, but not limited to, semiconductor wafers, flat panel displays (FPDs), and other microelectronic substrates.

### BACKGROUND

Various polymers may be used in the manufacture of electronic devices, including, for instance, photoresists and organic-based dielectrics. Photoresists, for example, may be used throughout semiconductor device fabrication in photolithographic operations. A photoresist may be exposed to actinic radiation through a photomask. Where a positive-acting resist is used, exposure may cause a chemical reaction within the material resulting in a solubility increase in aqueous alkali, allowing it to be dissolved and rinsed away with developer. Where a negative-acting resist is used, cross-linking of the polymer may occur in the exposed regions while leaving unexposed regions unchanged. The unexposed regions may be subject to dissolution and rinsing by a suitable developer chemistry. Following development, a resist mask may be left behind. The design and geometry of the resist mask may dependent upon the positive or negative tone of the resist; positive tone resist may match the design of the photomask, while a negative tone resist may provide a pattern that is opposite the photomask design. The use of photoresists may require several cleaning steps with a final clean of the mask before the next circuit design process step is implemented.

Organic-based dielectrics represent engineering polymers used to offer insulative properties to the microelectronic circuit. Examples of these chemistries include polyimide (PI) and poly-(p-phenylene-2,6-benzobisoxazole) (PBO) as manufactured by Hitachi-DuPont Microsystems. Another exemplary organic-based dielectric for electronic applications is bisbenzocyclobutene (BCB), manufactured by the USA-based, Dow Chemical Company. These polymers may be applied to the substrate in a similar fashion as photoresists using conventional spin, spray, or they may be slit-coated (which can be done, for instance in manufacturing FPDs). For these application reasons, organic-based dielectrics may often be referred to as spin-on dielectrics. Once the polymer is applied, the organic-based dielectrics may undergo a patterning process, but ultimately all of these systems lead to a final-stage cure, which may permanently fix the material in place by undergoing chemical and physical property changes. The final material may, for instance, exhibit both electrical and physical properties desirable for performance of the electric circuit. Once these organic-based dielectrics are fully cured, they are considered to be permanent, whereby, the need for rework would either require the use of aggressive materials such as strong acids or bases that likely would attack the substrate or adjacent metals or more practically, the rework condition would be considered as not commercially viable.

Positive photoresists may be based upon resins of the Novolac or polyhydroxystyrene (Phost) varieties chosen for high-resolution device processing in front-end semiconductor and flat panel display manufacturing. Positive-tone systems represent the largest volume portion of photoresists produced globally and there are many suppliers. Exemplary suppliers of these systems for both semiconductor and FPD include, but are not limited to, the USA-based AZ Electronic Materials, the USA-based Rohm and Haas Company, and the Japanese company, Tokyo Ohka Kogyo Co. Ltd. In positive photoresist applications, a substrate may be etched by plasma processes, which may use gases of inert and chemical varieties to, for instance, produce both ionized and reactive species that travel through the mask and etch down into the substrate. During etching, ionized and reactive species may combine with atoms of the substrate, form a by-product, and that by-product is vented away via the reduced pressure of the plasma system. These same gaseous species may also impact the photoresist mask, for instance, by baking it into place and also ejecting carbon-containing byproducts into the plasma. Photoresist by-products may mix with other species in the plasma and are continually directed down towards the substrate. These materials may condense to form a residue along the sidewalls of the etched features, producing a condition otherwise referred to as anisotropic etching, whereby species are highly controlled and directed into the substrate with little or no lateral loss. Upon completion, this etch residue may be removed along with the resist mask to prevent potentially deleterious effects on subsequent processes and lead to reduced device performance or device failure. Such residues and their associated resist masks, however, can be difficult to remove, normally involving the use of formulated stripper chemistries.

Negative photoresists may be chosen for more rigorous process conditions whereby more aggressive chemical or thermal exposure processes may be used. These negative photoresists include, but are not limited to, isoprene (rubber), acrylic, and epoxy-based resins. Cyclized isoprene (rubber) photoresists may be chosen for their high chemical resistance. Examples of these photoresists, for example, may be obtained from Fujifilm Electronic Materials, Ltd. under the trade name SC-RESIST or HNR-RESIST. Negative-tone isoprene resin resists may be used in aluminum processing where a brief chemical etch may be used to remove metal surrounding the masked feature. Negative-tone acrylic photoresists may be chosen for wafer-level-packaging bump formation. Suppliers include, but are not limited to, the USA-based Printed Circuits Division of E. I. duPont de Nemours and Company under the trade name RISTON, and the Japan's JSR Corporation for dry-film and spin-on (wet) negative acrylics, respectively. Dry-film and spin-on acrylics may offer an ability to deposit thick layers from 25 microns (μm) to 120 microns (μm), used to pattern the corresponding solder bumps. Once the pattern is formed, metal deposition may occur by electroplating or screen-printing, a process that may expose the resist to heated acid or baking in excess of 250° C., respectively. Another exemplary negative resist is an epoxy system under the trade name of SU-8™, originally developed by International Business Machines (IBM) and now sold by the USA company, MicroChem Corporation, and Gersteltec Engineering Solutions, a Swiss-based company. The SU-8™ may be chosen for thick patterns that may exceed 300 microns, with a high-aspect ratio (i.e., height vs. width), and with the pattern definition to exhibit straight sidewalls. Because of the unique characteristics of the SU-8™ epoxy resin, photoresists of this variety may be chosen to manufacture large devices, and may include microeletromechanical systems (MEMS). The varieties of negative-tone photoresists may be different from positive, their cleaning (removal) practice may be even more rigorous. The SU-8™ photoresist may be considered to be a permanent system, removed only with more complex, time, and costly practices.

As with many process involving photolithography, it may be desirable to completely remove the photoresist from the substrate before proceeding to the next process. Incomplete stripping of the photoresist may result in irregularities during the next etching or deposition step, which may cause quality and yield problems. For example, during solder bumping, resist contamination may prevent metal solder from wetting to a metal pad during the board assembly reflow processes, resulting in yield loss in a finished assembly. The same photoresist contamination may be manifested as organic contamination in front end of line device patterning and may result in the same non-wetting problems in an etch or deposition process. Such irregularities, no matter how small, may continue to magnify the problem throughout manufacturing until, during final device assembly and testing, the condition may lead to poor mechanical and electrical contacts, which produce high resistance and heat, or worse, catastrophic electrical shorting.

Throughout each of these chemical processes, selectivity in cleanliness and high throughput should be met without failure. Any problems associated with a lack of performance, presence of residue, or worse, a rise in process complexity, all may result in reduced yield and increased cost.

The chemistry of positive-tone resists may be hydrophilic (polar) and amorphous (i.e., non thermoset and cross-linked), and it may be easier to clean (remove) using conventional solvents and/or chemical strippers. The resins for positive-tone chemistries may be based upon either Novolac (cresol, phenol-formaldehyde) or polyhydroxystyrene (Phost), with options of styrenated copolymer and/or acrylic/PMMA (polymethylmethacrylate). These chemistries may offer good adhesion and fixing to a wide variety of surfaces while the hydroxyl groups present in the various forms of Novolac (i.e. cresol, bis-phenol, etc.) may provide intermolecular hydrogen bonding that aids in aqueous solubility. This condition may combine during the photoconversion of the initiator diazonaphthoquinone (DNQ) in Novolac systems, while in Phost systems, the acid catalyzed de-protection of the ester forms the more soluble alcohol. When used during operating conditions up to and including 100° C., these systems remain soluble in polar solvents while their UV-exposure will produce counterparts that are soluble in aqueous-base.

The positive-tone resists may be used as primary imaging masks for plasma-based etching. During this process, species in the plasma may produce etch residue while exposing the mask to temperatures exceeding 150° C. Etch residue (e.g. side-wall polymer) may be comprised of byproducts of the plasma with organic constituents of photoresist. The chemistry of the residue may comprise constituents of the substrate, metal topography, and plasma gases, to include silicon, gallium, arsenic, boron, phosphate, titantium, tantalum, tungsten, copper, nickel, aluminum, chromium, fluorine, chlorine, as well as carbon containing compounds. In Novolac systems that contain hydroxyl constituents, these elevated temperature exposure conditions may facilitate further reactions to form insoluble species. The reactivity of hydroxyl groups with halides and active metals, especially in the heated and acidic conditions of a plasma, to produce alkyl halides, esters, and, in some cases, high molecular weight polymers is known (Morrison, R. T. and Boyd, R. N., Organic Chemistry, 3rd ed., Allyn & Bacon, Inc., Boston Mass., Ch. 16 (1973)). Cleaning of etch residue and overexposed photoresist masks resulting from the effects of hot plasma etching may require the use of chemical strippers processed at elevated temperatures for extended periods of time dependent upon the process and tool.

Measurement used to predict stripping challenges of bulk resins includes, for instance, thermal analysis determination of glass transition (Tg). Relatively unchanged Tg values may be observed in positive-tone photoresists and similar amorphous systems (Fedynyshyn, T. et al., Proc. SPIE 6519, 65197-1 (2007)). Detectable increases of Tg in photoresists may be a function of the evaporative loss in solvent, which in turn, may depend upon the thickness of the photoresist coating. Most notable are observed increases in Tg with radiation and thermal exposure with polymer cross-linking (J. D. D'Amour et al., Proc. SPIE 5039, 966 (2003)). Such cross-linking of high temperature exposed Novolac resins and negative-tone systems is consistent with the presence of higher molecular weight species as detectable by increased values of Tg.

Cleaning (removal) of photoresist etch residue and the mask use complex chemical strippers composed of organic solvents, amines, water, reducing agents, chelating agents, corrosion inhibitors, and surfactants. The reducing agent, hydroxylamine, has been cited in the literature as a basic material that may facilitate dissolution of photoresist and its residue while offering protection of underlying aluminum metal features. The use of stripper chemistries may involve the delivery of large volumes of stripper to the substrate to be cleaned at a specific temperature for a given period of time.

As the industry continues to replace aluminum with copper to capture improved performance in their devices, the stripper chemistries must also be adjusted. Hydroxylamine may be acceptable for cleaning of aluminum devices; however, it may be too aggressive for copper. Device architecture using copper and low-K (dielectric constant, K), e.g. Cu/Low-K, may require fluorinated-based chemistries to remove silicon-laden etch residue. Amines and ammonia compounds are known to be complexing agents for Cu and may etch (attack) copper metal.

Negative photoresists used in forming wafer bumping metallization masks may include acrylic, styrenic, maleic anhydride or related monomers and copolymers. Such materials may be used to produce photosensitive thick films. These photoresists may be referred to as “acrylic” polymer systems due to the pendant groups on the main polymer chains, which include vinyl groups common to acrylics. The dry-film form of acrylic photoresists may be chosen where exposure to rigorous process conditions is required. As a result of this exposure, the cleaning of dry-film masks and residues may present a stripper challenge.

Resist stripping compositions that include aromatic quaternary ammonium hydroxide such as benzyltrimethylammonium hydroxide (BTMAH), a solvent such as an alkylsulfoxide, a glycol and a corrosion inhibitor and non-ionic surfactant may not completely remove many dry-film resists from a wafer surface. Similarly, compositions using pyrrolidone-based solvents such as N-methylpyrrolidone (NMP) exhibit the same drawback in that they cannot achieve complete removal of many dry-film resists. In general, compositions that include a quaternary ammonium hydroxide as tetramethylammonium hydroxide (TMAH) in NMP may not completely dissolve many dry-film resist. As discussed above, incomplete dissolution may produce particles that can become a source of contamination resulting in yield loss.

Similar experience may be noted for negative-tone photoresist of the rubber-based resin variety. Stripper chemistries that may be used to clean residue and masks resulting from rubber photoresists may include a hydrocarbon solvent and an acid, commonly a sulfonic acid. High acidity may be required for performance and emulsification of hydrolyzed rubber components. Representative inhibitors include, but are not limited to, mercaptobenzotriazole (MBT) and related triazoles to, for instance, prohibit attack upon adjacent metallic features. An exemplary inhibitor for these chemistries includes catachol, a toxic and carcinogenic material. Further, rinse steps for hydrocarbon strippers of this variety should use isopropanol (IPA) or related neutral and compatible solvents. This rinse practice, albeit a cost increase, may reduce the effects of metal attack to adjacent metals due to a pH-drop during water mixing with constituents of the stripper. Due to compatibility issues, wastes from the use of hydrocarbon-based strippers should be segregated from normal organic streams in a microelectronic fabrication.

Further, a cleaning tool may provide control in the process. Variability between part batches may be reduced by the operation of the tool. Barring any mixing or chemical adjustments made by the unit, the variables available to the tool for control include temperature, agitation, and time. With an ever-present intensive pressure to increase throughput in a manufacturing line, a constant emphasis is to decrease the process time. Again, without a change in chemistry, temperature and/or agitation may be increased with the expectation that polymer dissolution rates may increase resulting in shorter process time. However, other reactions that are contradictory to the objectives of the process, such as corrosion rate, may also increase with increased temperature and/or agitation. Continued loading of the stripper chemistry with the organic substance may cause a reduction in bath life and may accelerate the observation of residue or other phenomena that indicate a drop in performance. Further all wafers do not experience the exact same stripping environment, thus causing some amount of process variation.

On the temperature continuum, bath life may be facilitated by increasing temperature and/or agitation. Where agitation should be controlled to protect substrate features, bath life conditions may be increased through increased polymer dissolution with increasing temperature. There is a fundamental safety limit as communicated by industry guidelines (SEMI S3-91, Safety Guidelines for Heated Chemical Baths). Particularly when processing in baths, in accordance with SEMI, liquid over temperature shall be controlled at not more than 10° C. above the normal operating temperature of the liquid, where the typical operating temperature does not exceed the flashpoint of the liquid. Many companies set policy that is more restrictive such as operating at 10° C. below the flashpoint and setting the over temperature to be the flashpoint. These criteria and others may be observed in the processing of flat panel displays (FPDs).

Resist stripping at an FPD manufacturing plant may occur on large substrates traveling on a conveyor from one chamber to another. The resist may be stripped from the panel by a stripper delivered by a sprayer that floods the entire glass surface, traveling to a rinse stage where distilled, deionized, or demineralized water or an alternative solvent may be sprayed onto the surface, and the process may be completed with a drying step that may include a hot air knife. Stripping may be supported by at least two product tanks that are separate and distinct and arranged in-line with the flow direction of the parts. Substrates entering the tool may be first “washed” by the chemistry in the first tank. The stripper may be sprayed onto the substrate surface, and upon reacting with the resist and flowing off of the substrate, it may be collected and returned to the tank where it may then be heated and filtered such that any suspended and undissolved materials may be removed from the bulk chemistry. The filtered and heated stripper may be then cycled back to the spray chamber where it may be delivered to the substrate in a continuous manner that optimizes the resist stripping process.

As the part travels on the conveyor from the first chamber supported by tank #1 to the next chamber supported by tank #2, there may be a purity change in the stripper. Although the conditions of operation for tank #2 may be the same as that for tank #1, the amount of resist present may be lower than that for tank #1. Typical processing times may be defined for chamber #1 to offer a dwell time of the chemistry in contact with the resist that may optimize resist stripping and maximum removal. Over time, tank #1 may reach a maximum loading capacity for dissolved resist and a decision to replace the contents may be necessary. When this occurs, the contents of tank #1 may be sent to waste and replaced by the contents of tank #2. The contents of tank #2 may be replaced with fresh stripper (i.e. pure stripper). In this manner, the system may be said to operate in a counter-current fashion. Namely, the process flow of parts may be “counter” or opposite to the flow direction of the chemistry. By using this practice, tanks #1 and #2 may become the dirty and clean tanks, respectively. In other words, the unwanted resist may be concentrated in the front of the line while the cleanest chemistries remain near the end whereby after this point, the product substrate may be rinsed and dried.

The configuration given above for the FPD example may be consistent with many, if not all, in-line bench style tools and with many batch style-processing tools. In a bench tool, parts may move from one station to another while the tanks are at fixed locations. In a batch style tool, the parts may rotate but remain at a fixed location, while the chemistry may be delivered by spraying. There may be two tanks, the tool may pump from one or the other and carry-out counter-current cleaning designs by the use of “dirty” and “clean” tanks.

There is a yet unsatisfied need to achieve selectivity during processing with these formulated strippers. Namely, as the use of more aggressive chemistries may be put into practice to achieve a desired cleaning performance in ever reducing time, this practice should be met without damage to sensitive metals and the underlying substrate. This may be challenging as many of the acids or alkalis of choice may rapidly “spike” the pH of the system, once they are mixed with water during the rinse step, causing galvanic corrosion to substrate metals. During the rinse stage on a FPD line, water may be sprayed on the heated glass surface that contains residual stripper. No surfactants are used in a FPD line, in fear that a foam condition may occur and cause catastrophic failing of filters, pumping of dry air bubbles, and worse, contaminating the fabrication facilities by overflowing stripper that may trigger electrical shorting and lead to a fire. Since no surfactants are used, there may be irregular diffusion due to rising surface tension from the organic stripper to the aqueous condition. Irregular mixing and spreading may cause momentary dead spots on the panel, which may contribute to accelerated corrosion. The corrosive by-product and foaming condition may be avoided through rinsing with neutral solvents such as isopropanol (IPA). Although this practice may be acceptable to several FPD manufacturers, it is expensive and a flammability hazard.

There is a need, accordingly, for improved stripping compositions that may remove the processed resist in a rapid manner while maintaining safety towards the underlying metallurgy during rinsing with distilled, deionized, or demineralized water, and preventing corroding, gouging, dissolving, dulling, or otherwise marring the surfaces throughout the entire process. Further, growing initiatives exist within the industry to move toward being “green.” A green process and the associated chemistries are those which may reduce or eliminate the use and generation of hazardous substances. According to the American Chemical Society's Green Chemistry Institute, there are twelve (12) principles that help to define a green chemistry.

Where organic dielectrics are used, there may be a continuing need for processes and compositions that may be used to effectively re-work a cured polymer by dissolving and cleaning the unwanted material from the underlying substrate. In cases of positive photoresists, there may be a similar and continuing need for processes and compositions to effectively remove polymer from a substrate without deleterious effects to adjacent metal features. Finally, in the case of negative-tone photoresists, the same need exists for processes and compositions to effectively remove polymer from a substrate without deleterious effects to adjacent metal features.

While there is a desire to address the removal needs of organic substances with unique compositions, there also, is a challenge to design a process that is supported by a tool that may enable rapid processing of parts, rinsing with water, without deleterious effects to the substrate. There is a continuing emphasis for the microelectronics industry to be green through improving the safety of operations, reducing the use of chemistry, and reducing the generation of hazardous waste. Taking these challenges together, there is a need to provide a consistent and universal process, which uses compositions of matter that vary depending upon the performance needs of the polymer or residue to be removed, which provides high performance, high throughput, a green process, at a reduced cost of ownership.

### SUMMARY

One embodiment of the present disclosure concerns a composition comprising:
at least one solvent;
at least one amine;
at least one sulfonated polymer; and
at least one monomer that is a mono-amide or a diamide, alone or further in combination with a diester,
wherein the at least one solvent comprises at least one ethylene glycol moiety or at least one propylene glycol moiety and wherein the length of the at least one glycol moiety or the at least one propylene glycol moiety ranges from 1 to 5 carbon atoms;
wherein at least one end group of the at least one solvent comprises ether functionality or alkyl ether functionality; and wherein the length of at least one endgroup ranges from 1 to 6 carbon atoms. Another embodiment of the present disclosure concerns a composition comprising:
at least one solvent;
at least one amine; and
at least one monomer that is a mono-amide or a diamide, alone or further in combination with a diester,
wherein the at least one solvent comprises at least one ethylene glycol moiety or at least one propylene glycol moiety and wherein the length of the at least one glycol moiety or the at least one propylene glycol moiety ranges from 1 to 5 carbon atoms;
wherein at least one end group of the at least one solvent comprises ether functionality or alkyl ether functionality; and wherein the length of at least one endgroup ranges from 1 to 6 carbon atoms.

Yet another embodiment of the present disclosure concerns a method for removing at least one substance from at least one substrate comprising:
(a) coating a substance with a composition comprising:
   i. at least one solvent;
   ii. at least one amine;
   iii. at least one water soluble, water dispersible, or water dissipatable polymer; and
   iv. at least one monomer that is a mono-amide or a diamide, alone or further in combination with a diester,
(b) heating a substrate to a temperature and for a time sufficient to achieve removal of the substance, and
(c) rinsing the substrate with a volume of a rinsing agent sufficient to remove the composition and the substance.

A further embodiment of the present disclosure concerns a method for removing at least one substance from at least one substrate comprising:
(a) coating a substance with a composition comprising:
   i. at least one solvent;
   ii. at least one amine;
   iii. at least one water soluble, water dispersible, or water dissipatable polymer; and
   iv. at least one monomer that is a mono-amide or a diamide, alone or further in combination with a diester,
(b) heating a substrate to a temperature and for a time sufficient to achieve removal of the substance, and
(c) rinsing the substrate with a volume of a rinsing agent sufficient to remove the composition and the substance.

Still a further embodiment of the present disclosure concerns a method for removing at least one substance from at least one substrate comprising:
(a) coating a substance with a composition comprising:
   i. at least one solvent;
   ii. at least one amine; and
   iii. at least one monomer that is a mono-amide or a diamide, alone or further in combination with a diester,
(b) heating a substrate to a temperature and for a time sufficient to achieve removal of the substance, and
(c) rinsing the substrate with a volume of a rinsing agent sufficient to remove the composition and the substance.

Another embodiment of the present disclosure concerns a composition produced by combining:

at least one solvent at a weight percent ranging from 0.5% to 99.5%;

at least one amine; and
at least one sulfonated polymer at weight percent ranging from 0.5 to 99.5%.

Yet another embodiment of the present disclosure concerns a composition produced by combining:

at least one solvent at a weight percent ranging from 0.5% to 99.5%;

at least one amine; and
at least one sulfonated monomer at weight percent ranging from 0.1% to 99.5%.

### DETAILED DESCRIPTION

The present disclosure provides stripping compositions and methods, which may quickly and effectively remove polymeric organic substances from, for instance, inorganic substrates, including metallic, non-metallic, and metalized non-metallic substrates or from, for instance, organic substrates, including polymeric substrates, plastics, and wood based substrates or from, for instance, carbon based materials, including graphene, graphite and organic siloxanes, e.g, silsesquioxane

In an embodiment, the stripping composition comprises a water-soluble sulfonated polymer or sulfonated monomer and various additives, which effectively remove organic substances and their residues of thermoplastic or thermoset nature that comprise the basis for fabricating microcircuits in electronic manufacturing. According to one embodiment, the process may define a practice of coating the composition onto the substrate, heating the substrate to a specific temperature for a given time sufficient to achieve modification including both dissolution and/or release of the organic substance, and finishing with removal of the by-product by rinsing with a rinsing agent, such as water. The composition and method may work together to provide performance and other desired goals in manufacturing that may not be seen in conventional stripper processes. Although the organic substances to be removed may be cured to a hard and chemically resistant framework when exposed to the customer's process, the compositions and methods of the present disclosure are found to maintain acceptable performance.

The compositions and methods of the present disclosure may have particular applicability to semiconductor wafer fabrication, for example, in the removal of organic films and residues from semiconductor wafers. Such organic substances are present, for example, on post-etched wafers during front-end processing or in back-end wafer-level-packaging during a wafer bumping process. The compositions and methods are particularly suitable for the removal from wafers of hard-to-remove materials such as full-cure polyimide and dry-film photoresist residues.

While the present disclosure provides stripping compositions and methods that can effectively remove polymeric organic substances from a substrate, it may also be adapted for removing photoresists that include positive-tone of both Novolac (i.e. cresol formaldehyde) and polyhydroxy styrene (Phost), negative-tone varieties to include acrylics, isoprene (i.e. rubber), and epoxy (i.e. SU-8™), as well as dielectrics to include polyimide, polybenzoxazole (PBO), and bisbenzocyclobutene (BCB). The compositions and methods may also remove other photoresists, for example, multi-layer photoresists and chemically amplified photoresists. These organic substances may be employed in the fabrication of substrates, for example, the electronic devices on substrates such as wafers or flat panel displays, which may include various layers and structures such as metal, semiconductor, and the associated organic materials. Exemplary substrate materials include, for example, semiconductor materials such as silicon, gallium arsenide, indium phosphide, and sapphire, as well as glass and ceramic.

Whenever the term “water-dissipatable” or “water-dispersible” is used in this description, it may be understood to refer to the activity of a water or aqueous solution on the monomer or polymer (Component B). The term is specifically intended to cover those situations wherein a water or aqueous solution dissolves and/or disperses the monomer or polymer material therein and/or therethrough.

The terms “stripping,” “removing,” and “cleaning” are used interchangeably throughout this specification. Likewise, the terms “stripper,” “remover,” and “cleaning composition” are used interchangeably. The term “coating” is defined as a method for applying a film to a substrate such as spray coating, puddle coating, slit-coating or immersing. The terms “film” or “coating” are used interchangeably. The indefinite articles “a” and “an” are intended to include both the singular and the plural. All ranges are inclusive and combinable in any order except where it is clear that such numerical ranges are constrained to add up to 100%. The term “wt %” means weight percent based on the total weight of the components of the stripping composition, unless otherwise indicated.

A process according to the present disclosure may involve submerging the inorganic substrate in a bath of the composition according to the present disclosure or by applying the composition as a coating to the substrate. Once the substrate is submerged in the composition or the composition is applied and covers, or coats, the entire area, heating of the substrate may begin. A rapid rate of heating may occur until the desired temperature is reached and is held for a desired period of time. Alternatively, the bath into which the substrate is submerged maybe maintained at the desired temperature. Rinsing with a rinsing agent may occur and may be followed by a drying step. The total method of practice may involve three (3) distinct steps, namely, coating, heating, and rinsing. However, the steps are not required to be carried out in the order provided. For example, the substrate may first be heated before application of coating. As used herein, the term “rinsing agent” includes any solvent that removes the composition and material to be stripped. Examples of rinsing agents include, but are not limited to, water, pH modified water, acetone, alcohols, for example, isopropyl alcohol and methanol, Dimethylsulfoxide (DMSO), N-methylpyrrolidone (NMP), Glycol Palmitate, Polysorbate 80, Polysorbate 60, Polysorbate 20, Sodium Lauryl Sulfate, Coco Glucoside, Lauryl-7 Sulfate, Sodium Lauryl Glucose Carboxylate, Lauryl Glucoside, Disodium Cocoyl Glutamate, Laureth-7 Citrate, Disodium Cocoamphodiacetate, nonionic Gemini surfactants including, for example, those sold under the tradename ENVIROGEM 360, Oxirane polymer surfactants including, for example, those sold under the tradename SURFYNOL 2502, and poloxamine surfactants, including, for example, those sold under the tradename TETRONIC 701 and mixtures thereof. Further, the rinsing agent can be water containing a sulfonated monomer or polymer according to the invention in an amount ranging from less than 1% to the limit of solubility.

An embodiment of the disclosure concerns a method whereby a composition according to the present disclosure or other stripping composition is applied as a liquid coating in direct contact with the substance to be removed. In one embodiment, the method includes heating anywhere from 25° C. to 400° C. In another embodiment, the method includes heating anywhere from 100° C. to 250° C., for instance from 100° C. to 200° C. According to one embodiment, the process includes heating to a temperature above the flash point of the organic solvent that is present in the stripping composition. Variability in temperature may depend upon the nature and thickness of the organic substance. The heating step process time may, for instance, range from 5 seconds to 10 minutes, from 10 seconds to 8 minutes, or even from 30 seconds to 4 minutes. Moreover, the entire process time may, for instance, range from less than 15 seconds to 180 seconds or from 5 minutes to 10 minutes. The variability in time may depend upon the material to be removed, its thickness, and exposure condition. For example, for a Phost or Novolac resin, the heating step could be from 15 seconds to 1 minute. However, for other, more highly cured resins, the heating step may last from 2 to 4 minutes or even longer. Once the diffusion of the organic substance is complete, rinsing with a rinsing agent such as distilled, deionized, or demineralized water may be performed.

Rinsing may be facilitated by the presence of the water-soluble monomer or polymer in the composition. This monomer or polymer performs as a carrier system for the organic substance to be removed from the substrate. The rinsing agent used for rinsing can be at a temperature ranging from 5° C. to 100° C. However, rinsing may also occur at room temperature and may perform two objectives, to remove the dissolved organic substance, and to reduce the temperature of the substrate such that next stage processing may proceed.

Compositions of matter used in this disclosure include a major component to be a solvent system of the varieties that may include one or more esters selected from the group consisting of structures (I) R—CO₂R₁, glycol ether esters of structures (II) R₂—CO₂C₂H₄(OC₂H₄)ₙ—OR₃, (III) R₄—CO2C3H₆(OC₃H₆)ₙ—OR₅ and (IV) R₆OCO₂R₇, alcohols selected from structures (V) R₈OH, (VI) R₉OC₂H₄(OC₂H₄)ₙOH, (VII) R₁₀OC₃H₆(OC₃H₆)ₙOH, (VIII) R₁₁(OC₂H₄)ₙOH, and (IX) R₁₂(OC₃H₆)ₙOH, ketones selected from structures (X) R₁₃COR₁₄, sulfoxides selected from structure (XI) R₁₅SOR₁₆, and amides such as N,N-dimethyl formamide, N,N-dimethyl acetamide, and N-methylpyrolidone, wherein R, R₁, R₂, R₃, R₄, R₅, R₆, R₇, R₈, R₉, R₁₀, R₁₁, R₁₂, R₁₃, R₁₄, R₁₅, and R₁₆ are independently selected from hydrogen or C₁-C₁₄-alkyl groups and n represents a repeating unit ranging from 1 to 10. Further, suitable solvents include, but are not limited to, ketones such as cyclohexanone, 2-heptanone, methyl propyl ketone, and methyl amyl ketone, esters such as isopropyl acetate, ethyl acetate, butyl acetate, ethyl propionate, methyl propionate, gamma-butyrolactone (BLO), ethyl 2-hydroxypropionate (ethyl lactate (EL)), ethyl 2-hydroxy-2-methyl propionate, ethyl hydroxyacetate, ethyl 2-hydroxy-3-methyl butanoate, methyl 3-methoxypropionate, ethyl 3-methoxy propionate, ethyl 3-ethoxypropionate, methyl 3-ethoxy propionate, methyl pyruvate, and ethyl pyruvate, ethers and glycol ethers such as diisopropyl ether, ethyleneglycol monomethyl ether, ethyleneglycol monoethyl ether, and propylene glycol monomethyl ether (PGME), glycol ether esters such as ethyleneglycol monoethyl ether acetate, propyleneglycol methyl ether acetate (PGMEA), and propyleneglycol propyl ether acetate, aromatic solvents such as methylbenzene, dimethylbenzene, anisole, and nitrobenzene, amide solvents such as N,N-dimethylacetamide (DMAC), N,N-dimethylformamide, and N-methylformanilide, and pyrrolidones such as N-methylpyrrolidone (NMP), N-ethylpyrrolidone (NEP), dimethylpiperidone, 2-pyrrole, N-hydroxyethyl-2-pyrrolidone (HEP), N-cyclohexyl-2-pyrrolidone (CHP), and sulfur containing solvents such as dimethyl sulfoxide (DMSO), dimethyl sulfone and tetramethylene sulfone. Although these organic solvents may be used either individually or in combination (i.e., as mixtures with others), some embodiments of the solvent system contain diethylene glycol (DEG, Eastman Chemical Company), diethylene glycol monomethyl ether (DM SOLVENT, Eastman Chemical

Company), diethylene glycol monoethyl ether (DE SOLVENT, Eastman Chemical Company), or diethylene glycol monopropyl ether (DP SOLVENT, Eastman Chemical Company), diethylene glycol monobutyl ether (DB SOLVENT, Eastman Chemical Company) halogenated solvents including, for example, benzylchloride, hydrocarbon based solvents including, for example, those sold under the tradenames AROMATIC 100 and AROMATIC 150, sulfuric acid, or mixtures thereof.

According to another embodiment, the compositions of the present disclosure comprise one or more solvents chosen from solvents comprising at least one ethylene glycol moiety or at least one propylene glycol moiety, wherein the length of the at least one ethylene glycol moiety or the at least one propylene glycol moiety ranges from 1 to 5 carbon atoms. Further, at least one end group of the solvent comprises ether functionality or alkyl ether functionality where the at least one end group has a length ranging from 1 to 6 carbon atoms.

In some embodiments, the solvent is selected from the one or more of ethylene glycol, diethylene glycol, propylene glycol, diethylene glycol ethyl ether, diethylene glycol methyl ether, diethylene glycol butyl ether, diethylene glycol propyl ether, ethylene glycol propyl ether, ethylene glycol butyl ether, and mixtures thereof.

An embodiment of the composition includes at least one solvent at a weight percent ranging from 0.5 weight percent to 99.5 weight percent. In one embodiment, the solvent is present in the solvent composition at a weight percent ranging from 40% to 97% or at a weight percent from 60% to 90%.

In an embodiment, the composition also contains a monomer, which exhibits the property of water solubility, water dispersibility, or water dissipatability present in a range from 0.1 to 99.5 weight percent and derived from, but not limited to, multifunctional sulfomonomers containing at least one metal sulfonate group attached to an aromatic nucleus that are water soluble or water dispersible or water dissipatable determined 0.1 weight percent, for instance 0.5 weight percent concentration or more (i.e. monomer in water) and the metal of the sulfonate group is Na, Li, K, NH₄ and mixtures thereof. The composition includes at least one of these said monomers at 0.1 weight percent to 99.5 weight percent. In one embodiment, the monomer is present in the composition at a weight percent ranging from 0.5 to 99.5 or at a weight percent ranging from 0.1 to 5 or at a weight percent ranging from 1 to 5 or at a weight percent ranging from 2 to 59 or at a weight percent ranging from 5 weight percent to 35 weight percent.

Examples of water soluble monomers may be selected from metal sulfonate salts of isophthalic acid, terephthalic acid, succinic acid, methylene carboxylic acid, and benzoic acid; metal sulfonate salts of a diester of isophthalic acid, terephthalic acid, succinic acid, methylene carboxylic acid, and benzoic acid; or a combination thereof, wherein the sulfonate group is attached to the aromatic nucleus and the metal is selected from lithium, sodium, or potassium and mixtures thereof. In Exemplary monomers include, but are not limited to, 5-sodiosulfoisophthalic acid and salts and esters of the same, such as, the diethylene glycol diester of 5-sodiosulfoisophthalic acid.

In some embodiments, the composition may contain a polymer, which exhibits the property of water solubility, water dispersibility, or water dissipatability present at a range from 0.5 to 99.5 weight percent and derived from, but not limited to, alcohol ethoxylates, bisphenol ethoxylates and propoxylates, alkylbenzene salts, cellulose acetate phthalate, cellulosic derivatives of alkoxyethyl and hydroxypropyl, copolymers of ethylene and propylene oxide, dendritic polyesters, ethoxylated amines, ethoxylated alcohol salts, ethylene acrylic acid, hydroxy-methacrylates, phosphate esters, polyethylene glycols, polyethylene imine, polyethylene oxides, polyvinyl alcohol, polyvinyl pyrollidinone, starch, styrene maleic anhydride, sulfonated acrylics, sulfonated polystyrenes, sulfonated polyamides, sulfopolyester of the linear or branched formula, or rosin acids. The composition may include one or more of these polymers at 1.0 weight percent to 99.5 weight percent. In one embodiment, the polymer is present in the solvent composition at a weight percent ranging from 5.0 to 99.5 or at a weight percent ranging from 10 to 99.5 or at a weight percent ranging from 5.0 to 25.0 or at a weight percent ranging from 1.5 to 60.0 or at a weight percent ranging from 2.0 to 30.0 or at a weight percent ranging from 12.0 to 60.0 or at a weight percent ranging from 15.0 to 30.0.

In an embodiment, the water soluble polymer includes one or more sulfonated polyesters (sulfopolyesters) of the linear or branched varieties respectively, or mixtures thereof. The sulfopolyester is comprised of
(i) monomer residues of at least one dicarboxylic acid; and
(ii) 4 to 25 mole percent, based on the total of all acid and hydroxyl equivalents, of monomer residues of at least one difunctional sulfomonomer containing at least one metal sulfonate group bonded to an aromatic ring, wherein the functional groups are hydroxy or carboxyl or amino and the metal of the sulfonate group is Na, Li, K, Mg, Ca, Cu, Ni, Fe and mixtures thereof; and optionally
(iii) monomer residues of at least one poly(alkyene glycol) having the formula
(OCH₂CH₂)ₙ— wherein n is 2 to 500, provided that the mole percent of such residues in inversely proportional to the value of n; and
(iv) up to 75 mole percent of monomer residues of at least one diol, wherein said diol is other than a poly(alkylene glycol).

Suitable sulfopolyester polymers for use in this invention are those known as Eastman AQ® POLYMERS and Eastman AQ COPOLYESTERS. Exemplary polymers may include, but are not limited to, polymers prepared from dimethyl-5-sodiosulfoisophthalate and its parent acid and salts, which may be derived from such co-monomers as isophthalic acid, terephthalic acid, succinic acid, benzoic acid, methylene carboxylic acid and their esters. Diols may be used with such acid co-monomers such as, for example, diethylene glycol, ethylene glycol, triethylene glycol, polyethylene glycol, propylene glycol, 2-methyl propane diol, neopentyl glycol, 1,6-hexanediol, and mixtures thereof.

The polymer may be selected from water soluble, water dispersible, or water-dissipating sulfopolyesters or polyesteramides (herein after referred to collectively as sulfopolyesters) containing ether groups and sulfonate groups having a glycol residue and a dicarboxylic acid residue and at least one difunctional co-monomer containing a sulfonate group attached to an aromatic nucleus and in the form of a metallic salt. Such polymers are well known to those skilled in the art and are available from Eastman Chemical Company under the tradename of Eastman AQ POLYMERS. In particular, such sulfopolyesters can be dissolved, dispersed or otherwise dissipated in aqueous dispersions, preferably at temperatures of less than 80° C. The term “residue” or “component” as used in the specification and concluding claims refers to the moiety that is the resulting product of the chemical species in a particular reaction scheme or later formulation or chemical product, regardless of whether the moiety is actually obtained from the chemical species. Thus, for example, an ethylene glycol residue in a polyester refers to one or more —OCH₂CH₂O— repeat units in the polyester, regardless of whether ethylene glycol is used to prepare the polyester.

The aforedescribed polyester material may be prepared by any method known to one of ordinary skill in the art. The use of the term “acid” in the above description and in the appended claims includes the various ester forming or condensable derivatives of the acid reactants such as the dimethyl esters thereof as employed in the preparations set out in these patents. Examples of sulfo-monomers are those wherein the sulfonate group is attached to an aromatic nucleus such as benzene, naphthalene, biphenyl, or the like, or wherein the nucleus is cycloaliphatic such as in 1,4-cyclohexanedicarboxylic acid.

As an alternative to the sulfonated polymer or monomer, the composition may include a sulfonated hydrotrope. Representative hydroptropes include, for example, xylene sulfonate or an ionomer, chosen from, for example, sulfonated polyamides and sulfonated polystyrenes. A “hydrotrope” as used herein refers to an organic substance that increases the solubility of surfactants and other substances in an aqueous solution. Hydrotropes are not surfactants; they do not adsorb onto the surface or interface and do not form micelles.

Additives to the composition may comprise 100 parts-per-million (ppm) to 99 weight percent of an alkali or acid of organic or inorganic origin to include ammonium hydroxide, quaternary hydroxides or tetra-alkyl ammonium hydroxides or mixed alkyl/aryl ammonium hydroxide, such as tetramethyl ammonium hydroxide (TMAH), tetraethyl ammonium hydroxide (TEAH), and benzyltrimethyl ammonium hydroxide (BTMAH), amines such as triethylene tetramine, alkanolamines that include monoethanolamine, monoisopropanolamine, diglycolamine, elemental hydroxides, or alkoxides such as potassium tertiary butyl hydroxide (KTB), alkyl-sulfonic acids such as methanesulfonic (MSA), toluenesulfonic (TSA), and dodecylbenzene sulfonic acid (DDBSA), formic acid, fatty acids, sulfuric acid, nitric acid, or phosphoric acids; an inhibitor defined as a protecting agent for substrate composition that may include chelating, complexing, or reducing agents, comprising at least one of the known varieties, including benzylic hydroxides such as catechol, triazoles, imidazoles, borates, phosphates, and alkyl or elemental silicates, ethylenediaminetetraacetic acid, diethylenetriaminepentaacetic acid, nitrilotriacetic acid, and 2,4-pentanedione, reducing sugars, hydroquinones, glyoxal, salicylaldehyde, acids such as citric and ascorbic acid, hydroxylamines, or vanillin; and a surfactant chosen from one or more of the known varieties, including nonionic nonyl-phenols and nonyl-ethoxylates, nonionic Triton and PEG-based surfactants, anionic forms that include alkyl-sulfonates, phosphate esters, succinates, sodium sulfonated dodecylbenzene, and fluorinated systems and cationic forms that include quaternary ammonium compounds, polyoxyethylene based amines and imiazoline based surfactants. The additive may be present in an amount ranging from 0.1 weight percent to 95 weight percent, 1.0 weight percent to 50 weight percent, or 5.0 weight percent to 35 weight percent.

The cleaning composition of the present disclosure can be semi-aqueous or non-aqueous. Water may be added in any amount to achieve the desired cleaning composition. Exemplary compositions may include water in an amount from 5 weight % to 80 weight %, for instance from 10 weight % to 80 weight %, for instance 20 weight % to 80 weight %.

In one embodiment, the cleaning composition includes at least one organic solvent at a weight percent ranging from 0.5% to 99.0%, at least one sulfonated polymer or monomer at weight percent ranging from 0.5% to 99.0%, and at least one additive that enhances cleaning performance at a weight percent ranging from 0.01% to 99.0%.

In another embodiment, the cleaning composition includes the solvent at a weight percent ranging from 30% to 95%, the monomer or polymer at a weight percent ranging from 0.25% to 60%, and the additive at a weight percent ranging from 2% to 60%.

The composition may also include an inhibitor that acts as a protecting agent for the substrate composition. The inhibitors include chelating, complexing, or reducing agents, comprising one or more of the known varieties, including benzylic hydroxides such as catechol, triazoles, imidazoles, borates, phosphates, and alkyl or elemental silicates, ethylenediaminetetraacetic acid, diethylenetriaminepentaacetic acid, nitrilotriacetic acid, and 2,4-pentanedione, reducing sugars, hydroquinones, glyoxal, salicylaldehyde, fatty acids such as citric and ascorbic acid, hydroxylamines, or vanillin.

In one embodiment, the composition includes at least one compound that includes a nitrogen substituent that will react with at least one ester on the polymer or monomer to form an amide. In another embodiment, the at least one compound that includes a nitrogen substituent is an additive. In yet another embodiment, the at least one compound that includes a nitrogen substituent is an inhibitor. In one embodiment, the at least one compound that includes a nitrogen substituent reacts with two esters on the polymer or monomer to form a diamide in a composition of the present disclosure. In one embodiment, the at least one compound that includes a nitrogen substituent reacts with one ester on the polymer or monomer to form a mono-amide. In another embodiment, the at least one compound that includes a nitrogen substituent reacts with at least one diester on the polymer or monomer to form a composition comprising at least one diester, mono-amide, and diamide. In one embodiment, the at least one compound that includes a nitrogen substituent is an amine. Exemplary amines include, but are not limited to, triethylene tetramine, alkanolamines that include monoethanolamine, monoisopropanolamine, diglycolamine. In another embodiment, the at least one compound that includes a nitrogen substituent is nitric acid. In yet another embodiment, the at least one compound that includes a nitrogen substituent is chosen from triazoles, imidazoles, ethylenediaminetetraacetic acid, diethylenetriaminepentaacetic acid, nitrilotriacetic acid, hydroxylamines, and mixtures thereof. Nitrogen-containing compounds suitable for use herein would be readily apparent to one of ordinary skill in the art. In one embodiment, the at least one compound that includes a nitrogen substituent is present at a weight percent ranging from 0.01% to 99.0%.

The compositions according to the present disclosure may also include a surfactant including at least one of the known varieties, including nonionic nonyl-phenols and nonyl-ethoxylates, nonionic Triton and PEG-based surfactants, anionic forms that include alkyl-sulfonates, phosphate esters, and succinates, and fluorinated systems and cationic forms that include quaternary ammonium compounds, polyoxyethylene based amines and imiazoline based surfactants.

Contact may be made to the substrate by the composition via bath submersion or using a coating practice. In microelectronic manufacturing, spin coating may be a method of choice used to apply coatings to a substrate. However, other methods exist to include spray coating, spray-spin coating and slit coating for large substrates as in FPD manufacturing. In all cases, the objective is to apply the composition in a manner to achieve complete coverage. Many coating applications are concerned with a high degree of uniformity. In this disclosed method, the application of the coating is performed in a manner such that good control over the volume of the stripping composition applied to the substrate is maintained, for example to minimize the total volume of the stripping composition. In this disclosed method, a thickness shall be established, for instance on the order of a maximum value of 1000 microns (1 μm=1×10⁻⁶ m), but some cases where the organic substance is very thin, the composition thickness may be smaller. In one embodiment of the present disclosure, the coating can be up to 800 microns thick, from 200 to 600 microns thick, or from 300 to 400 microns thick.

Spin-coating the composition for this disclosure may involve dispensing the material at the center of a substrate, and operating the equipment at a low rate of circular motion speed (i.e. 100 revolutions per min, rpm, or less). Liquid delivery may be done by a static method, whereby the fluid may “puddle” onto the surface. A dynamic method may also be used where the material is dispensed when the substrate is already in motion. During the early stages for a new process set-up, the exact conditions of rpm and time may need to be established in such a manner to ensure complete coverage of the substrate with minimal or no waste. There is no need to be concerned with edge bead formation as this condition may be irrelevant to the process objective.

The manipulation of spin-speed may be a focus of many apparatus used in the microelectronics industry. Substrate rotation may have a direct affect on these properties and produce different coating results. At low spin-speeds, fluid mobility may be low with minor material loss, however, irregularities in substrate coverage may also occur. Alternatively, high spin-speeds may result in high mobility and high material loss. Although spin-coating is a standard practice in the industry, coatings of acceptable thickness uniformity may be achieved with a spray-coating practice. Once the coating is completed, heat activation of the process may immediately proceed.

Heat application may be conducted through several paths. A simple hot-plate may be used. This requires the substrate to be moved from one location to another. In situations where automation is of interest, the wafer may remain stationary while heat is applied using a base-chuck or an overhead convective source, e.g. hot metal plate or a radiative source, infrared heater or a combination thereof. Exact ergonomics and logistic concerns with respect to controls and throughput can be readily determined by those skilled in the art of tool design. Once the proper heating regime is followed, the composition and organic resin may be removed by rinsing with a rinsing agent either in an agitated batch or by direct spray contact.

The stripping compositions of the disclosure function by maintaining a solvency environment when used on amorphous organic substances such as positive-tone photoresists of the Phost or Novolac varieties. In such cases and when exposure conditions include moderate temperatures up to 150° C., a composition that contains the minimum constituents, including the solvent system and water soluble monomer, may be coated and processed at the conditions of the disclosure method. When heated to a sufficient temperature, rapid modification including dissolution may occur and diffusion of the photoresist into the composition proceeds rapidly to completion. Additives such as an alkali agent, inhibitor, and surfactant may be used to facilitate good results with highly baked (i.e. >150° C.) photoresists. Advantages in using additives contained within the stripping composition may include improved dissolution rates due to saponifying cross-linked photoresist while the inhibitors may protect exposed metal during the stripping and rinsing steps.

Organic alkanolamine compounds may be used for basic reactive modification and emulsification of the positive-tone photoresists, to include one or more low molecular weight candidates, for example, monoethanolamine (MEA), N-(2-aminoethyl)ethanolamine (AEEA), monoisopropanolamine (MIPA), or diglycolamine (DGA), and combinations thereof. In cases where a negative-tone acrylic photoresist or a cured thermoset polyimide are the candidates to be removed, the composition may require a strong alkali, namely, a quaternary hydroxide, metal hydroxide, or alkoxide.

Similar to the review given here for removing coatings and residues compositions also apply for removal of negative isoprene (rubber) resist and negative-epoxy (SU-8™) photoresist. As determined for the positive photoresist and negative acrylic and polyimide, the choice in composition is dependent upon the material to remove. For negative-isoprene, the chemistry is hydrophobic (non-polar) and the cross-linked rubber system does not respond to alkalis, only acids. Rubber photoresists may require aromatic solvents and hydrophobic acids, such as dodecylbenzene sulfonic acid. For negative epoxy photorest, the chemistry is hydrophilic (polar) and like the rubber photoresists, these systems also may not respond to alkalis. In one embodiment, the system is one that incorporates hydrophilic acids such as methanesulfonic acid (MSA) or sulfuric acid. These systems may contain the water soluble polymer or monomer, to facilitate proper rinsing following modification including dissolution and/or release of the photoresist.

### EXAMPLES

The disclosure is further illustrated, without limitation, by the following examples. All percentages given are by weight unless otherwise specified. In these examples, the measurement of performance and selectivity of the present disclosure is conducted using practices readily accepted by the industry. In such cases, measurement is made by optical microscope and where necessary, the use of etch rate determinations by high sensitivity gravimetric reviews on metallic substrates, and where necessary, more detailed studies were conducted using scanning electron microscopy (SEM). In the following examples, silicon wafers were used as the inorganic substrate upon which the organic substance is applied and cured. The following items in Table 1 represent the organic substances to be removed, their preparation methods, and the sources from which they were procured.

TABLE 1
List of Organic Resins Used to Demonstrate the Disclosure.

| Example | | | | |
|---|---|---|---|---|
| # | Material | Form | Type | Description/Manufacturer |
| 1 | Phost | Solid resin | Amorphous, | Equal quantities as 1:1 |
| | | worked up | positive | w/wwt % PB5 and PB5W |
| | | as liquid | | resin (Hydrite Chemical |
| | | | | Co., Brookfield WI), |
| | | | | dissolved in PGMEA* |
| | | | | as 20 wt % solids |
| 2 | Novolac | Solid resin | Amorphous, | Equal quantities as 1:1 |
| | | worked up | positive | w/wwt % REZICURE 5200 |
| | | as liquid | | and 3100 (SI |
| | | | | Group, Schenectady, NY), |
| | | | | dissolved in PGMEA* |
| | | | | as 20 wt % solids |
| 3 | Acrylic | Dry-film | Thermoset, | Shipley GA-series (GA-20) |
| | | | negative | removed and applied direct, |
| | | | | (Rhom & Haas, Inc. |
| | | | | Marlborough, MA) |
| 4 | Polyimide | Liquid | Thermoset, | PI-2611 (HD |
| | | | Non- | Microsystems, |
| | | | photoactive | Parlin, NJ) |
| 5 | Isoprene | Liquid | Thermoset, | SC-RESIST (Fujifilm |
| | | | negative | Electronic Materials, |
| | | | | North Kingston, RI) |

*PGMEA: propylene glycol monomethyl ether acetate

Where applicable, the organic substance was applied in the manner of a coating using a Brewer Science, Inc. CB-100 coater and following standard protocol for applying the liquid form of the polymer material to the inorganic substrate. Once the material was coated, it was sent to a soft bake step for a short 60 second hot plate bake at 100° C. For negative Acrylic resist, the material was exposed to ultraviolet light of a broad-band type emitting at 365 nanometers and of a high exposure dose of 0.12 W/cm²-sec, for an excessive period of 30 minutes. Following exposure, the wafer was post-exposure baked at a predetermined hard bake temperature and time depending on the resist. Once the wafer samples have been prepared, they are staged for experimentation. The experiments in Examples 2-5 were all conducted identical to each other using the same wafers and handling practices. Each wafer was staged in the work station where the disclosure may be demonstrated. Compositions of the disclosure are prepared ahead of time and also set aside. The inventive method was tested by applying the composition of interest to a portion of the wafer surface. The wafer was then immediately transferred to a hot plate that had been preset at the desired processing temperature. Once the wafer was set onto the hot plate, a digital timer was started. Once the pre-established time has expired, the wafer was removed and immediately rinsed with distilled, deionized, or demineralized water from a wash bottle. The rinsed wafer was observed and set aside to dry. Additional observations were taken and the results were recorded.

In Examples 1-7, introduction of the monomer was obtained by the addition of a premade stock solution. These stock solutions were comprised of a hydrophilic solvent (Component A) and a water soluble or water dispersible or water dissipatable monomer (Component B). The monomers chosen were selected from various multifunctional sulfomonomers containing at least one metal sulfonate group attached to an aromatic nucleaus that are water soluble or water dispersible or water dissipatible determined to be at or greater than 0.5 weight percent concentration (i.e. monomer in water). Such monomers are well known to those skilled in the art and include such monomers as the lithium and sodium salts of diethylene glycol diesters of 5-sulfoisophthalic acid, ethylene glycol diesters of 5-sulfoisphthalic acid, alkyl diesters of 5-sulfoisophthalic acid, aryl diesters of 5-sulfoisophthalic acid, and 5-sulfoisophthalic acid. Other monomers include salts of phenolsulfonates, alkoxybenzenesulfonates, and aryloxybenzenesulfonates. The solvents chosen were ethylene glycol, diethylene glycol, triethylene glycol, propylene glycol, diethylene glycol methyl ether (Eastman DM SOLVENT), diethylene glycol ethyl ether (Eastman DE SOLVENT), diethylene glycol propyl ether (Eastman DP SOLVENT), diethylene glycol butyl ether (Eastman DB SOLVENT), ethylene glycol propyl ether (Eastman EP SOLVENT), and ethylene glycol butyl ether (Eastman EB SOLVENT). In a screening study, solutions were attempted for each of the monomer and solvent pairings at 10, 20, and 30 wt % solids. These stock solutions were prepared by adding the solvent to a round-bottomed flask with an agitator, condenser, and nitrogen source connected. The appropriate amount of the monomer was then added, and the mixture was heated with agitation until the solution was obtained.

The tables include description of the cleaning composition by weight percent of the components and the cleaning conditions employed to test effectiveness of the cleaning process. The term “Clean” means complete removal of photoresist resin by visual inspection, “Not Clean” means partial removal of photoresist resin by visual inspection, and “No Change” means no indication that photoresist resin was attacked under process conditions by visual inspection. Solutions of the sodium salt of the diethylene glycol diester of 5-sulfoisophthalic acid (I) in diethylene glycol (DEG) are used to illustrate the invention in the following examples. Example 3 illustrates the use of other 5-sulfoisophthalic monomers.

In Examples 9-14, introduction of the sulfopolyester was obtained by the addition of a premade stock solution. These stock solutions were comprised of a hydrophilic solvent (Component A) and a water soluble or water dispersible or water dissipatable polymer (Component B). The polymers chosen were various sulfopolyesters of different glass transition temperatures and viscosities of both the linear and branched varieties. Such polymers are well known to those skilled in the art and are available, for instance, from Eastman Chemical Company under the tradename of Eastman AQ POLYMERS. In particular, such sulfopolyesters can be dissolved, dispersed or otherwise dissipated in aqueous dispersions, for instance, at temperatures of 80° C. or less. The polyesters considered as candidates for the invention include, but are not limited to, Eastman AQ 38S POLYMER, Eastman AQ 48 ULTRA POLYMER, Eastman AQ 55S POLYMER, EastONE S85030 COPOLYESTER, Eastman ES-100 WATER-DISPERSIBLE POLYMER, Eastman AQ 1350 COPOLYESTER, and Eastman AQ 2350 COPOLYESTER. The solvents chosen were ethylene glycol, diethylene glycol, triethylene glycol, propylene glycol, diethylene glycol methyl ether (Eastman DM SOLVENT), diethylene glycol ethyl ether (Eastman DE SOLVENT), diethylene glycol propyl ether (Eastman DP SOLVENT), diethylene glycol butyl ether (Eastman DB SOLVENT), ethylene glycol propyl ether (Eastman EP SOLVENT), and ethylene glycol butyl ether (Eastman EB SOLVENT). In a screening study, solutions were attempted for each of the polymer and solvent pairings at 10, 20, and 30 wt % solids. In addition, solutions of Eastman AQ 38S POLYMER and Eastman AQ 48 ULTRA POLYMER each at 40 wt % solids were attempted in the four Diethylene glycol ether solvents. These stock solutions were prepared by adding the solvent to a round-bottomed flask with an agitator, condenser, and nitrogen source connected. The appropriate amount of the solid sulfopolyester was then added, and the mixture was heated with agitation until the solution was obtained. Depending on the polymer and solvent pairing and the solids loading, the solutions were heated to different temperatures for various times ranging from 90° C. for 30 minutes to 180° C. for 70 minutes. Table 2 below summarizes these stock solutions. “Suitable Solutions” are those in which the polyester dissolved readily under preparation conditions, remained soluble on cooling, and the solution was suitable for making a coating. “Bad Solutions” are those in which either the solids were insoluble in the solvents under the preparation conditions or the solution formed was unstable in the short term. “Disqualified Solutions” are those in which a solution of the same polymer and solvent paring had previously formed a bad solution at a lower solids loading. “Questionable Solutions” are those in which the solutions formed were either extremely viscous or exhibited signs of potential long-term instability, but might be of value for further study.

TABLE 2
Summaryof Potential Stock Solutions

| Solution | AQ- | AQ- | AQ- | ES- | | AQ- | AQ- |
|---|---|---|---|---|---|---|---|
| Status | 38 | 48 | 55 | 100 | EastONE | 1350 | 2350 |
| Suitable | 20 | 21 | 3 | 1 | 1 | 18 | 6 |
| Solutions | | | | | | | |
| Questionable | 0 | 3 | 2 | 1 | 3 | 2 | 1 |
| Solutions | | | | | | | |
| Bad Solutions | 11 | 8 | 20 | 12 | 17 | 6 | 15 |
| Disqualified | 3 | 2 | 5 | 16 | 9 | 4 | 8 |
| Solutions | | | | | | | |
| Total Solutions | 34 | 34 | 30 | 30 | 30 | 30 | 30 |

Based on this screening study, eighty-two suitable and questionable solutions were tested on both Phost and Novolac coated wafers that had in both cases been cured at 150° C. for 15 minutes. In each case, a small amount of solution was applied to resin coated wafer, the wafer was immediately heated to 100° C. for 60 seconds, then immediately washed with a stream of water at ambient temperature. A simple visual observation was used to evaluate completeness of resin removal. Only those blends that were judged to exhibit excellent cleaning performance by visual examination were deemed as passing. Table 3 summarizes the results.

TABLE 3
Cleaning of Novolac (N) and Phost (P): (C—Cleaned; F—Failed)

| Wt % Solid | | 10% | | 20% | | 30% | | 40% | |
|---|---|---|---|---|---|---|---|---|---|
| Solvent | Sulfopolyester | P | N | P | N | P | N | P | N |
| Ethylene glycol | AQ-1350 | C | F | | | | | | |
| Ethylene glycol | AQ-38 | C | F | C | F | | | | |
| Ethylene glycol | AQ-48 | C | F | C | F | | | | |
| Ethylene glycol | AQ-55 | C | C | | | | | | |
| Ethylene glycol | EastONE | C | F | | | | | | |
| Ethylene glycol | ES-100 | C | F | | | | | | |
| Diethylene | AQ-1350 | C | F | | | | | | |
| glycol | | | | | | | | | |
| Diethylene | AQ-38 | C | C | C | C | | | | |
| glycol | | | | | | | | | |
| Diethylene | AQ-48 | C | C | C | C | | | | |
| glycol | | | | | | | | | |
| Diethylene | AQ-55 | C | C | | | | | | |
| glycol | | | | | | | | | |
| Propylene | AQ-48 | | | C | F | | | | |
| glycol | | | | | | | | | |
| Propylene | AQ-55 | | | C | F | | | | |
| glycol | | | | | | | | | |
| DM Solvent | AQ-1350 | C | C | C | F | C | F | | |
| DM Solvent | AQ-2350 | C | C | C | F | F | F | | |
| DM Solvent | AQ-38 | C | C | C | F | C | F | F | F |
| DM Solvent | AQ-48 | C | C | C | C | C | F | C | F |
| DE Solvent | AQ-1350 | C | C | C | F | C | F | | |
| DE Solvent | AQ-2350 | C | F | C | F | C | F | | |
| DE Solvent | AQ-38 | C | C | C | C | F | F | C | F |
| DE Solvent | AQ-48 | C | C | C | C | C | F | C | C |
| DP Solvent | AQ-1350 | C | C | C | F | C | C | | |
| DP Solvent | AQ-38 | F | F | C | C | C | C | C | C |
| DP Solvent | AQ-48 | C | C | C | C | C | F | F | F |
| DB Solvent | AQ-1350 | C | C | C | F | C | F | | |
| DB Solvent | AQ-38 | | | C | F | C | C | C | F |
| DB Solvent | AQ-48 | | | C | C | C | C | F | F |
| EP Solvent | AQ-1350 | C | F | C | F | C | C | | |
| EB Solvent | AQ-1350 | C | C | C | F | C | C | | |

The composition comprising diethylene glycol ethyl ether and Eastman AQ 48 ULTRA POLYMER at solids loadings ranging from 10 wt % all the way up to 40 wt % were found to exhibit broad performance cleaning both Phost and Novolac photoresist resin from silicon substrate. In addition, the various concentrations of these solutions were extremely stable even after several months of storage at room temperature.

Therefore, a composition comprising 20 wt % Eastman AQ 48 and 80 wt % diethylene glycol ethyl ether (Eastman DE SOLVENT) was selected as the suitable standard composition to be used in developing additive blends to target more exotic and more difficult to remove photoresists. This stock solution comprised 30% of the final solutions used to treat wafers in Examples 10-14, yielding 6 wt % sulfopolyester and 24 wt % DE SOLVENT in all of these solutions. Thus, examples 10-14 are to demonstrate how one skilled in the art may approach development of a composition according to this invention that is suitable for removal of an organic residue. Neither the selection of this standard composition for further studies nor the specific examples that follow are intended to limit the scope of this invention.

### Example 1

Table 4 contains the results from a cleaning study conducted for Novolac resin coated as described in Table 1. Resin was cured for 15 minutes at 200° C. Process temperatures for the cleaning stage were 100° C., 150° C., and 200° C.

TABLE 4

| Solution (wt %) | | | Process Conditions | | | |
|---|---|---|---|---|---|---|
| | | DE | 150° C. | 150° C. | 200° C. | 200° C. |
| I | DEG | Solvent | for 60 s | for 90 s | for 30 s | for 60 s |
| 29.64% | 70.36% | 0.00% | Not | Clean | Not | Clean |
| | | | Clean | | Clean | |
| 15.96% | 84.04% | 0.00% | Not | Clean | Not | Not |
| | | | Clean | | Clean | Clean |
| 25.08% | 74.92% | 0.00% | Clean | Clean | Clean | Clean |
| 15.96% | 38.04% | 46.00% | Not | Clean | Not | Not |
| | | | Clean | | Clean | Clean |
| 25.08% | 59.92% | 15.00% | Not | Clean | Not | Not |
| | | | Clean | | Clean | Clean |

I—Sodium salt of the diethylene glycol diester of 5-sulfoisophthalic acid
DEG—Diethylene glycol
DE Solvent—Diethylene glycol ethyl ether

### Example 2

Table 5 contains the results from a cleaning study conducted for Phost resin coated as described in Table 1. Resin was cured for 15 minutes at 200° C. All cleaning compositions are comprised of 6 wt % sulfopolyester, 24 wt % DE Solvent, with the remaining 70 wt % being comprised of two additives as noted in Table 6. Process temperatures for the cleaning stage were 100° C., 150° C., and 200° C.

TABLE 5

| Solution (wt %) | | | Process Conditions | | |
|---|---|---|---|---|---|
| | | DE | 100° C. for | 100° C. for | 150° C. for |
| I | DEG | Solvent | 30s | 60s | 60s |
| 29.64% | 70.36% | 0.00% | Clean | Clean | Clean |
| 15.96% | 84.04% | 0.00% | Clean | Clean | Clean |
| 25.08% | 74.92% | 0.00% | Clean | Clean | Clean |
| 15.96% | 38.04% | 46.00% | Clean | Clean | Clean |
| 25.08% | 59.92% | 15.00% | Clean | Clean | Clean |

I - Sodium salt of the diethylene glycol diester of 5-sulfoisophthalic acid
DEG - Diethylene glycol
DE Solvent - Diethylene glycol ethyl ether

Examples 1 and 2 demonstrate the utility of invention in cleaning cured Novolac and polyhydroxystyrene resins from silica wafers. In the case of polyhydroxystyrene resin (Example 2), all cleaning compositions were effective in removing cured resin using cleaning conditions of 100-150° C. from 30 seconds to 60 seconds. For Novolac resins (Example 1), cleaning required process temperatures greater than 100° C. to achieve satisfactory removal of resin although some removal is noted under all reported conditions. In both examples, it was found resins could be removed by compositions containing DE solvent. Addition of such solvent could benefit the management of viscosity as needed to utilize the invention in various coating process steps.

### Example 3

Table 6 contains the results from a cleaning study conducted to test compositions containing 20 weight percent 5-sodiosulfoisophthalic acid (SSIPA), 5-lithiosulfoisophthalic acid (LiSIPA), the ethylene glycol diester of 5-sodiosulfoisophthalic acid (EGSIPA diester), and the diethylene glycol ethyl ether diester of 5-sodiosulfoisophthalic acid (DESIPA diester) as cleaning compositions to remove Novolac and polyhydroxystyrene resins. Resins were cured for 15 minutes at 200° C. Process temperatures for the cleaning stage were 100° C. for 60 seconds.

TABLE 6

| | Wt % | | | |
|---|---|---|---|---|
| Monomer | Monomer | Solvent | Novolac | Phost |
| SSIPA | 20 | Diethylene glycol | No Change | No Change |
| LiSIPA | 20 | Diethylene glycol | Not Clean | Clean |
| EGSIPA | 20 | ethylene glycol | No Change | Clean |
| diester | | | | |
| DESIPA | 20 | Diethylene glycol | Not Clean | Clean |
| diester | | ethyl ether | | |

The data in Table 6 indicates compositions of ethylene glycol, diethylene glycol and diethylene glycol ethers containing lower molecular weight monomeric salts of 5-sulfosulfonic acid and related esters perform well as cleaning compositions to Phost resin, but little success cleaning Novolac resin.

### Example 4

Table 7 contains the results from a cleaning study conducted for polyimide resin coated as described in Table 1. Resin was cured for 15 minutes at 150° C. Process temperatures for the cleaning stage were 100° C., 150° C., and 200° C. at various durations of time. Results are tabulated below.

TABLE 7

| Solution (wt %) | | | | | | Process Conditions | | |
|---|---|---|---|---|---|---|---|---|
| | | DE | 2- | | | 150° C. | 200° C. | 200° C. |
| I | DEG | Solvent | Pyrolle | MEA | KTB | for 90 s | for 30 s | for 60 s |
| 8.89% | 21.11% | 0.00% | 28.00% | 35.00% | 7.00% | No | Not | Not |
| | | | | | | Change | Clean | Clean |
| 4.79% | 25.21% | 0.00% | 28.00% | 35.00% | 7.00% | No | Not | Clean |
| | | | | | | Change | Clean | |
| 7.52% | 22.48% | 0.00% | 28.00% | 35.00% | 7.00% | No | Clean | Not |
| | | | | | | Change | | Clean |
| 4.79% | 11.41% | 13.80% | 28.00% | 35.00% | 7.00% | No | Not | Not |
| | | | | | | Change | Clean | Clean |
| 7.52% | 17.98% | 4.50% | 28.00% | 35.00% | 7.00% | No | No | Not |
| | | | | | | Change | Change | Clean |

I—Sodium salt of the diethylene glycol diester of 5-sulfoisophthalic acid
DEG—Diethylene glycol
DE Solvent—Diethylene glycol ethyl ether
MEA—monoethanolamine
KTB—potassium tert-butoxide

Example 4 suggests that cured polyimide resin is more difficult to clean than either Phost or Novolac resin. Only the use of highly basic materials such as 2-pyrolle, MEA and KTB in the additive component produced desirable results on low temperature cleaned wafers. No evidence of attack is noted unless the temperature of the cleaning process is elevated to 200° C.

### Example 5

Table 8 contains the results from a cleaning study conducted for acrylic resin coated as described in Table 1. Resin was cured for 15 minutes at 150° C. Process temperatures for the cleaning stage were 100° C., 150° C., and 200° C. Results are tabulated below.

TABLE 8

| Solution (wt %) | | | | | | Process Conditions | | |
|---|---|---|---|---|---|---|---|---|
| | | DE | 2- | | | 150° C. | 200° C. | 200° C. |
| I | DEG | Solvent | Pyrolle | MEA | KTB | for 90 s | for 30 s | for 60 s |
| 8.89% | 21.11% | 0.00% | 28.00% | 35.00% | 7.00% | No | Not | Not |
| | | | | | | Change | Clean | Clean |
| 4.79% | 25.21% | 0.00% | 28.00% | 35.00% | 7.00% | No | Not | Clean |
| | | | | | | Change | Clean | |
| 7.52% | 22.48% | 0.00% | 28.00% | 35.00% | 7.00% | No | Clean | Not |
| | | | | | | Change | | Clean |
| 4.79% | 11.41% | 13.80% | 28.00% | 35.00% | 7.00% | No | Not | Not |
| | | | | | | Change | Clean | Clean |
| 7.52% | 17.98% | 4.50% | 28.00% | 35.00% | 7.00% | No | No | Not |
| | | | | | | Change | Change | Clean |

I—Sodium salt of the diethylene glycol diester of 5-sulfoisophthalic acid
DEG—Diethylene glycol
DE Solvent—Diethylene glycol ethyl ether
MEA—monoethanolamine
KTB—potassium tert-butoxide

Example 5 suggests that cured acrylic resin is more difficult to clean than either Phost or Novolac resin but requires conditions similar to polyimide resin for satisfactory removal of resin.

### Example 6

Table 9 contains the results from a cleaning study conducted for Isoprene resin coated as described in Table 1. Wafers were cured for 15 minutes at 150° C. Process temperatures for the cleaning stage were 100° C., 150° C., and 200° C.

TABLE 9

| | | | | Process Conditions | | | |
|---|---|---|---|---|---|---|---|
| Solution (wt %) | | | | 100° | 100° | 150° | 150° |
| | | Aromatic- | | C. for | C. for | C. for | C. for |
| Solids | DEG | 100 | DDBSA | 60 s | 90 s | 60 s | 90 s |
| 2.74% | 3.27% | 56.40% | 37.60% | Some | Clean | Clean | Clean |
| | | | | Clean | | | |
| 6.84% | 8.17% | 51.00% | 34.00% | Some | Clean | Clean | Clean |
| | | | | Clean | | | |
| 9.12% | 10.89% | 48.00% | 32.00% | Some | Clean | Clean | Clean |
| | | | | Clean | | | |

I—Sodium salt of the diethylene glycol diester of 5-sulfoisophthalic acid
DEG—Diethylene glycol
DE Solvent—Diethylene glycol ethyl ether

The cleaning compositions presented in Example 6 were designed to be hydrophobic (hydrocarbon) to allow penetration of the cleaning composition into the resin.

### Example 7

To further illustrate a method of the disclosure, wafers having a cured photoresist layer as described above were coated with formulations described in art as useful for removing photoresist by a known bath or soaking dissolution process.

Formulations were prepared according to Table 10 and applied to isoprene coated wafer pieces cured 15 minutes at 150° C. per Table 1. The wafer pieces were immediately heated to the target temperature for 60 seconds, and rinsed with water. The effectiveness of photoresist removal was judged by visual inspection.

TABLE 10
Cleaning Results for Isoprene Resin

| | | Additive A:B | | | |
|---|---|---|---|---|---|
| | | wt % | | | |
| Additive A | Additive B | Concentrations | 95° C. | 125° C. | 150° C. |
| ¹Aromatic 100 | ²DDBSA | 50:50 | Partial | Not | Partial |
| Fluid | | | Clean | Clean | Clean |
| ¹Aromatic 150 | ²DDBSA | 50:50 | Partial | Partial | Partial |
| Fluid | | | Clean | Clean | Clean |
| ¹Aromatic 200 | ²DDBSA | 50:50 | Clean | Partial | Partial |
| Fluid | | | | Clean | Clean |

¹Aromatic 100 Fluid, Aromatic 150 Fluid and Aromatic 200 Fluid from ExxonMobil Chemical
²DDBSA - dodecylbenzenesulfonic acid

### Example 8

Formulations were prepared according to Table 11 and applied to acrylic coated wafer pieces cured 15 minutes at 150° C. per Table 1. The wafer pieces were immediately heated to the target temperature for 60 seconds, and rinsed with water. The effectiveness of photoresist removal was judged by visual inspection.

TABLE 11
Cleaning Results for Acrylic Resin

| Additive | Additive | Additive | Additive | | | |
|---|---|---|---|---|---|---|
| A (%) | B (%) | C (%) | D (%) | 95° C. | 125° C. | 150° C. |
| ¹DGA(60) | ²HA(40) | — | — | Partial | Partial | Clean |
| | | | | Clean | Clean | |
| ³MEA (60) | HA (40) | — | — | Clean | No | No |
| | | | | | Clean | Clean |
| ⁴AEEA (60) | HA (30) | Water (10) | — | Partial | Partial | Partial |
| | | | | Clean | Clean | Clean |
| AEEA(35) | MEA(25) | HA(30) | Water (10) | Partial | Partial | Partial |
| | | | | Clean | Clean | Clean |
| DGA (40) | ⁵NMP(20) | HA(40) | — | Clean | Partial | Partial |
| | | | | | Clean | Clean |
| MEA (40) | NMP(20) | HA(40) | — | Partial | Partial | Partial |
| | | | | Clean | Clean | Clean |
| AEEA(40) | NMP(20) | HA(30) | Water (10) | Clean | Partial | No |
| | | | | | Clean | Clean |
| AEEA(25) | MEA(15) | NMP(20) | HA(40) | No | No | No |
| | | | | Clean | Clean | Clean |
| DGA (40) | ⁶DMAC(20) | HA(40) | — | Clean | Clean | Clean |
| MEA (40) | DMAC(20) | HA(40) | — | Clean | Partial | Clean |
| | | | | | Clean | |
| AEEA(40) | DMAC(20) | HA(30) | Water (10) | Partial | No | No |
| | | | | Clean | Clean | Clean |
| AEEA(25) | MEA(15) | DMAC(20) | HA(40) | Clean | No | No |
| | | | | | Clean | Clean |
| ⁷DMSO(70) | HA(30) | — | — | Clean | Partial | Partial |
| | | | | | Clean | Clean |
| DMSO(86) | ⁸DEGEE(6) | AEEA | ⁹TMAH | Clean | Clean | Partial |
| | | | | | | Clean |
| DMSO(88) | MEA(6) | TMAH(6) | | Partial | Partial | Partial |
| | | | | Clean | Clean | Clean |

¹DGA—diglycolamine
²HA—50% hydroxylamine in water
³MEA—monoethanolamine
⁴AEEA—N-(2-aminoethyl)ethanolamine
⁵NMP—N-methyl 2-pyrrolidinone
⁶DMAC—N,N-dimethyl acetamide
⁷DMSO—dimethylsulfoxide
⁸DEGEE—Diethylene glycol ethyl ether
⁹TMAH—tetramethylammonium hydroxide

The data contained in Tables 10 and 11 indicate many different formulations may be used to effect photoresist removal according to the method of the invention. It should be noted that high temperatures may cause the formation of a water insoluble haze or crust in some cases. This can be mitigated by temperature optimization.

### Example 9

In contrast with the over-all success of many compositions containing a sulfonated polyester, compositions containing other water soluble, dispersible, or dissipatable polymers did not perform nearly as well. In general, these other polymers were far less soluble in the chosen solvents. Process conditions for achieving the solutions again varied depending on the polymer and solvent pairing and the solids loading. In most cases, the solutions were heated to a temperature ranging from 120° C. for 30 minutes up to 180° C. for 80 minutes; however, the polyvinyl pyrollidone and the dendritic polyester were both noticeable exceptions that required far less heating. The results of the solubility study are tabulated below.

TABLE 12
Summary of Stock Solutions Not Containing
a Sulfonated Polyester

| Solution | | | | | | | | |
|---|---|---|---|---|---|---|---|---|
| Status | ¹DPE | ²AMP | ³PVP | ⁴SPS | ⁵HEC | ⁶XSS | ⁷PVME | ⁸CAP |
| Suitable | 0 | 1 | 40 | 0 | 0 | 0 | 10 | 8 |
| Solutions | | | | | | | | |
| Question- | 26 | 0 | 0 | 0 | 0 | 6 | 0 | 13 |
| able | | | | | | | | |
| Solutions | | | | | | | | |
| Bad | 0 | 10 | 0 | 11 | 10 | 4 | 2 | 3 |
| Solutions | | | | | | | | |
| Dis- | 4 | 19 | 0 | 19 | 20 | 20 | 18 | 6 |
| qualified | | | | | | | | |
| Solutions | | | | | | | | |
| Total | 30 | 30 | 40 | 30 | 30 | 30 | 30 | 30 |
| Solutions | | | | | | | | |

¹DPE—Dendritic Polyester
²AMP—Sulfonated acrylic
³PVP—Polyvinyl pyrollidone
⁴SPS—Sulfonated polystyrene
⁵HEC—Hydroxyethyl Cellulose
⁶XSS—Xylene sodium sulfonate
⁷PVME—Polyvinyl methyl ether
⁸CAP—Cellulose acetate phthalate

From the suitable and questionable blends prepared, a selection of 49 was tested on both PHOST and Novolac photoresist that had been cured at 150° C. for 15 minutes. In both cases, a small amount of each composition was applied to the resin coated wafer, heated to 100° C. for 60 seconds, and then immediately rinsed off with de-ionized water at ambient temperature. A simple visual inspection was subsequently made, and only those compositions judged to have excellent cleaning performance were deemed as passing. In many cases, only the 10 wt % solids blends were tested; however, solutions with up to 40 wt % solids of the polyvinyl pyrollidone were also tested because that particular polymer was so soluble in every solvent tested. With the exception of xylene sodium sulfonate, the results were almost wholly negative, and further testing was deemed unnecessary. The results of the performance screening are summarized below.

TABLE 13
Cleaning of Novolac (N) and PHOST (P):
(C—Cleaned; F—Failed)

| Wt % Solids | | 10% | | 20% | | 30% | | 40% | |
|---|---|---|---|---|---|---|---|---|---|
| Solvent | Polymer | P | N | P | N | P | N | P | N |
| Ethylene glycol | ¹AMP | C | F | | | | | | |
| Ethylene glycol | ²PVP | F | F | | | | | F | F |
| Diethylene | ³DPE | C | F | | | | | | |
| glycol | | | | | | | | | |
| Diethylene | PVP | F | F | | | | | F | F |
| glycol | | | | | | | | | |
| Diethylene | ⁴XSS | C | C | | | | | | |
| glycol | | | | | | | | | |
| Diethylene | ⁵CAP | C | F | | | | | | |
| glycol | | | | | | | | | |
| Triethylene | PVP | F | F | | | | | F | F |
| glycol | | | | | | | | | |
| Triethylene | XSS | C | F | | | | | | |
| glycol | | | | | | | | | |
| Triethylene | CAP | C | F | | | | | | |
| glycol | | | | | | | | | |
| Propylene | PVP | F | F | | | | | F | F |
| glycol | | | | | | | | | |
| Propylene | XSS | C | C | | | | | | |
| glycol | | | | | | | | | |
| DM Solvent | PVP | F | F | | | | | F | F |
| DM Solvent | XSS | C | C | | | | | | |
| DM Solvent | ⁶PVME | F | F | F | F | F | F | | |
| DM Solvent | CAP | F | F | C | F | | | | |
| DE Solvent | DPE | C | F | | | | | | |
| DE Solvent | PVP | F | F | | | | | F | F |
| DE Solvent | XSS | C | C | | | | | | |
| DE Solvent | PVME | F | F | F | F | F | F | | |
| DE Solvent | CAP | F | F | | | | | | |
| DP Solvent | DPE | F | F | | | | | | |
| DP Solvent | PVP | F | F | | | | | F | F |
| DP Solvent | XSS | C | F | | | | | | |
| DP Solvent | PVME | C | F | F | F | | | | |
| DP Solvent | CAP | F | F | | | | | | |
| DB Solvent | PVP | F | F | | | | | F | F |
| DB Solvent | PVME | C | F | C | F | | | | |
| DB Solvent | CAP | F | F | | | | | | |
| EP Solvent | DPE | F | F | | | | | | |
| EP Solvent | PVP | F | F | | | | | F | F |
| EP Solvent | CAP | F | F | | | | | | |
| EB Solvent | PVP | F | F | | | | | F | F |

¹AMP—Sulfonated acrylic
²PVP—Polyvinyl pyrollidone
³DPE—Dendritic Polyester
⁴XSS—Xylene sodium sulfonate
⁵CAP—Cellulose acetate phthalate
⁶PVME—Polyvinyl methyl ether

Very few solutions exhibited success in cleaning both PHOST and Novolac photoresist, and the few compositions that did have this success were questionable solutions that were non-ideal for use in this invention. By comparison, many compositions containing sulfonated polyesters exhibited much better performance dissolving PHOST and Novolac photoresist. The compositions containing sulfonated polyesters were significantly preferable to those containing any of the other polymers considered, and a single composition from those containing sulfonated polyesters was chosen for future testing.

### Example 10

Table 12 contains the results from a cleaning study conducted for PHost resin coated as described in Table 1. Resin was cured for 15 minutes at 200° C. All cleaning compositions are comprised of 6 wt % sulfopolyester, 24 wt % DE SOLVENT, with the remaining 70 wt % being comprised of two additives as noted in Table 14. Process temperatures for the cleaning stage were 100° C., 150° C., and 200° C.

TABLE 14
Cleaning Results for PHost Resin

| | | Additive A:B | | | |
|---|---|---|---|---|---|
| | | wt % | | | |
| Additive A | Additive B | Concentrations | 100° C. | 150° C. | 200° C. |
| ¹NMP | ²TMAH | 65:5 | Clean | Clean | Clean |
| NMP | TMAH | 50:20 | Clean | Clean | Clean |
| NMP | ³KTB | 65:5 | Clean | Clean | Clean |
| NMP | KTB | 50:20 | Clean | Clean | Clean |
| NMP | ⁴MEA | 65:5 | Clean | Not | Not |
| | | | | Clean | Clean |
| NMP | MEA | 50:20 | Clean | Clean | Not |
| | | | | | Clean |
| NMP | H₃PO₄ | 65:5 | Clean | Clean | Not |
| | | | | | Clean |
| NMP | H₃PO₄ | 50:20 | Clean | Clean | Clean |
| NMP | ⁵MSA | 65:5 | Clean | Clean | Clean, |
| | | | | | some |
| NMP | MSA | 50:20 | Clean | Clean | Clean |
| ⁶DMSO | TMAH | 65:5 | Clean | Clean | Clean |
| DMSO | TMAH | 50:20 | Clean | Clean | Clean |
| DMSO | KTB | 65:5 | Clean | Clean | Clean |
| DMSO | KTB | 50:20 | Clean | Clean | Clean |
| DMSO | MEA | 65:5 | Clean | Clean, | Not |
| | | | | most | Clean |
| DMSO | MEA | 50:20 | Clean | Clean | Not |
| | | | | | Clean |
| DMSO | H₃PO₄ | 65:5 | Clean | Clean, | Clean |
| | | | | most | |
| DMSO | H₃PO₄ | 50:20 | Clean | Clean | Clean |
| DMSO | MSA | 65:5 | Clean | Not | Not |
| | | | | Clean | Clean |
| DMSO | MSA | 50:20 | Clean | Clean | Clean |

¹NMP - N-methyl-2-pyrrolidone
²TMAH - Tetramethylammonium hydroxide (20 wt % in propylene glycol)
³KTB - Potassium tert-butoxide (20 wt % in propylene glycol)
⁴MEA - Monoethanol amine
⁵MSA - Methanesulfonic acid
⁶DMSO - Dimethylsulfoxide

The data in Table 12 suggest that most solutions will perform well in dissolving and removing the PHost resin, even at high exposure temperatures of 200° C. The solutions enriched with higher concentrations of acid or base additives exhibited improved results. At both levels of enrichment, solutions containing MEA did not perform well removing PHost cured at high temperatures. The primary conclusion here is that PHost is relatively easy to process at 60 seconds with the invention method and compositions.

### Example 11

Table 13 contains the results from a cleaning study conducted for Novolac resin coated as described in Table 1. Resin was cured for 15 minutes at 200° C. All cleaning compositions were comprised of 6 wt % sulfopolyester, 24 wt % DE Solvent, with the remaining 70 wt % being comprised of two additives as noted in Table 15. Process temperatures for the cleaning stage were 100° C., 150° C., and 200° C.

TABLE 15
Cleaning Results for Novolac Resin

| | | Additive A:B | | | |
|---|---|---|---|---|---|
| | | wt % | | | |
| Additive A | Additive B | Concentrations | 100° C. | 150° C. | 200° C. |
| ¹NMP | ²TMAH | 65:5 | Clean | Not | Clean |
| | | | | Clean | |
| NMP | TMAH | 50:20 | Not | Clean | Clean |
| | | | Clean | | |
| NMP | ³KTB | 65:5 | Clean | Clean | Not |
| | | | | | Clean |
| NMP | KTB | 50:20 | Clean | Clean | Clean |
| NMP | ⁴MEA | 65:5 | Clean | Clean | Not |
| | | | | | Clean |
| NMP | MEA | 50:20 | Clean | Clean | Not |
| | | | | | Clean |
| NMP | H₃PO₄ | 65:5 | Not | Clean | Not |
| | | | Clean | | Clean |
| NMP | H₃PO₄ | 50:20 | Not | Clean | Clean |
| | | | Clean | | |
| NMP | ⁵MSA | 65:5 | Clean | Clean | Not |
| | | | | | Clean |
| NMP | MSA | 50:20 | Clean | Clean | Clean |
| ⁶DMSO | TMAH | 65:5 | Clean | Clean | Clean |
| DMSO | TMAH | 50:20 | Clean | Clean | Clean |
| DMSO | KTB | 65:5 | Clean | Clean | Clean |
| DMSO | KTB | 50:20 | Clean | Clean | Clean |
| DMSO | MEA | 65:5 | Clean | Not | Not |
| | | | | Clean | Clean |
| DMSO | MEA | 50:20 | Clean | Clean | Not |
| | | | | | Clean |
| DMSO | H₃PO₄ | 65:5 | Not | Clean | Not |
| | | | Clean | | Clean |
| DMSO | H₃PO₄ | 50:20 | Not | Not | Not |
| | | | Clean | Clean | Clean |
| DMSO | MSA | 65:5 | Clean | Not | Not |
| | | | | Clean | Clean |
| DMSO | MSA | 50:20 | Clean | Clean | Not |
| | | | | | Clean |

¹NMP - N-methyl-2-pyrrolidone
²TMAH - Tetramethylammonium hydroxide (20 wt % in propylene glycol)
³KTB - Potassium tert-butoxide (20 wt % in propylene glycol)
⁴MEA - Monoethanol amine
⁵MSA - Methanesulfonic acid
⁶DMSO - Dimethylsulfoxide

Table 13 suggests that most additive combinations are suitable for cleaning cured Novolac resin from silica substrates; however, some difficulty is encountered when cleaning at 200° C. Acidic solutions do not produce desirable results especially on highly cured novolac resin, with phosphoric acid containing compositions failing in nearly every attempt.

### Example 12

Table 14 contains the results from a cleaning study conducted for acrylic resin coated as described in Table 1. Resin was cured for 15 minutes at 150° C. All cleaning compositions were comprised of 6 wt % sulfopolyester, 24 wt % DE Solvent, with the remaining 70 wt % being comprised of two additives as noted in Table 16. Process temperatures for the cleaning stage were 100° C., 150° C., and 200° C. Results are tabulated below.

TABLE 16
Cleaning Results for Acrylic Resin

| Additive | Additive | Additive A:B wt % | | | |
|---|---|---|---|---|---|
| A | B | Concentrations | 100° C. | 150° C. | 200° C. |
| ¹NMP | ²TMAH | 65:5 | Clean | Partial | Partial |
| | | | | Clean | Clean |
| NMP | TMAH | 50:20 | Clean | Partial | Clean |
| | | | | Clean | |
| NMP | ³KTB | 65:5 | Clean | Partial | Partial |
| | | | | Clean | Clean |
| NMP | KTB | 50:20 | Clean | Clean | Partial |
| | | | | | Clean |
| NMP | ⁴MEA | 65:5 | Clean | Partial | Partial |
| | | | | Clean | Clean |
| NMP | MEA | 50:20 | Partial | Partial | Partial |
| | | | Clean | Clean | Clean |
| NMP | H₃PO₄ | 65:5 | Partial | Partial | Partial |
| | | | Clean | Clean | Clean |
| NMP | H₃PO₄ | 50:20 | Partial | Partial | No |
| | | | Clean | Clean | Clean |
| NMP | ⁵MSA | 65:5 | Partial | Partial | Partial |
| | | | Clean | Clean | Clean |
| NMP | MSA | 50:20 | Partial | Partial | Partial |
| | | | Clean | Clean | Clean |
| ⁶DMSO | TMAH | 65:5 | Clean | Partial | Partial |
| | | | | Clean | Clean |
| DMSO | TMAH | 50:20 | Clean | Partial | Clean |
| | | | | Clean | |
| DMSO | KTB | 65:5 | Clean | Partial | Partial |
| | | | | Clean | Clean |
| DMSO | KTB | 50:20 | Partial | Partial | Partial |
| | | | Clean | Clean | Clean |
| DMSO | MEA | 65:5 | Clean | Partial | Partial |
| | | | | Clean | Clean |
| DMSO | MEA | 50:20 | Clean | Partial | Partial |
| | | | | Clean | Clean |
| DMSO | H₃PO₄ | 65:5 | Partial | Partial | Partial |
| | | | Clean | Clean | Clean |
| DMSO | H₃PO₄ | 50:20 | Not | Not | Not |
| | | | Clean | Clean | Clean |
| DMSO | MSA | 65:5 | Partial | Partial | Partial |
| | | | Clean | Clean | Clean |
| DMSO | MSA | 50:20 | Partial | Partial | Partial |
| | | | Clean | Clean | Clean |

¹NMP - N-methyl-2-pyrrolidone
²TMAH - Tetramethylammonium hydroxide (20 wt % in propylene glycol)
³KTB - Potassium tert-butoxide (20 wt % in propylene glycol)
⁴MEA - Monoethanol amine
⁵MSA - Methanesulfonic acid
⁶DMSO - Dimethylsulfoxide

Table 14 suggests that cured acrylic resin is more difficult to clean than either PHOST or novolac resin. Only the use of highly basic materials such as TMAH, MEA, or KTB in the additive component produced desirable results on low temperature cleaned wafers.

### Example 13

Table 15 contains the results from a cleaning study conducted for Polyimide resin coated as described in Table 1. After the soft bake, wafers were cured for 15 minutes at 200° C. followed by an additional 30 minutes at 350° C. All cleaning compositions were comprised of 6 wt % sulfopolyester, 24 wt % DE Solvent, with the remaining 70 wt % being comprised of three additives as noted in Table 17. Process temperatures for the cleaning stage were 100° C., 150° C., and 200° C. Results are tabulated below.

TABLE 17
Cleaning Results for Polyimide Resin

| | | | Additive | | | |
|---|---|---|---|---|---|---|
| Additive | Additive | Additive | A:B:C wt % | 100° | 150° | 200° |
| A | B | C | Concentrations | C. | C. | C. |
| ¹NMP | DMSO | MEA | 23.5:23.5:23 | Not | Not | Not |
| | | | | clean | clean | clean |
| NMP | DMSO | ³KTB | 23.5:23.5:23 | Not | Clean | Clean |
| | | | | clean | | |
| NMP | DMSO | ²TMAH | 23.5:23.5:23 | Not | Clean | Clean |
| | | | | clean | | |
| NMP | ⁵Surf | ⁴MEA | 46:2:22 | Not | Not | Not |
| | | | | clean | clean | clean |
| NMP | Surf | KTB | 46:2:22 | Not | Clean | Clean |
| | | | | clean | | |
| NMP | Surf | TMAH | 46:2:22 | Clean | Clean | Clean |
| DMSO | None | MEA | 47:23 | Not | Not | Not |
| | | | | clean | clean | clean |
| DMSO | None | KTB | 47:23 | Not | Not | Clean |
| | | | | clean | clean | |
| DMSO | None | TMAH | 47:23 | Not | Clean | Clean |
| | | | | clean | | |
| DMSO | Surf | MEA | 46:2:22 | Not | Not | Not |
| | | | | clean | clean | clean |
| DMSO | Surf | KTB | 46:2:22 | Not | Clean | Clean |
| | | | | clean | | |
| DMSO | Surf | TMAH | 46:2:22 | Not | Clean | Clean |
| | | | | clean | | |
| DMSO | ⁷DMSO₂ | ⁸KTB + | 27.5:23.5:23 | Not | Clean | Clean |
| | | MEA | | clean | | |
| NMP | DMSO | ⁸KTB + | 27.5:23.5:23 | Not | Clean | Clean |
| | | MEA | | clean | | |

¹NMP—N-methyl-2-pyrrolidone
²TMAH—Tetramethylammonium hydroxide (20 wt % in propylene glycol)
³KTB—Potassium tert-butoxide (20 wt % in propylene glycol)
⁴MEA—Monoethanol amine
⁵Surf—Nonionic alkyl polyethylene glycol ether surfactant
⁶DMSO—Dimethylsulfoxide
⁷DMSO₂—Dimethylsulfone
⁸KTB + MEA—equal weights of 20 wt % potassium t-butoxide in propylene glycol and monoethanol amine

Table 15 suggests that higher process temperatures yield best results for cleaning polyimide resin from inorganic substrates. Virtually no good results were observed at a process temperature of 100° C. Additionally, polyimide removal required a strong alkali component with a pKa equal to or greater than 12. In all instances where MEA is present alone in the composition as the only alkali, cleaning results were not acceptable. The presence of KTB or TMAH did promote good results.

### Example 14

Table 16 contains the results from a cleaning study conducted for Isoprene resin coated as described in Table 1. Wafers were cured for 15 minutes at 150° C. All cleaning compositions were comprised of 6 wt % sulfopolyester, 24 wt % DE Solvent, with 68 wt % being comprised of two additives as noted in Table 15 and 2 wt % being comprised of a surfactant such as Zelec™ UN (alkoxyphosphate ester surfactant). Process temperatures for the cleaning stage were 100° C., 150° C., and 200° C.

TABLE 18
Cleaning Results for Isoprene Resin

| | | Additive A:B | | | |
|---|---|---|---|---|---|
| | | wt % | | | |
| Additive A | Additive B | Concentrations | 100° C. | 150° C. | 200° C. |
| ¹Aromatic 150 | ²DDBSA | 41:27 | Not | Clean | Clean |
| Fluid | | | Clean | | |
| 1-Dodecene | DDBSA | 41:27 | Not | Clean | Clean |
| | | | Clean | | |

¹Aromatic 150 Fluid from ExxonMobil Chemical
²DDBSA - dodecylbenzenesulfonic acid

The cleaning composition presented in Table 18 was designed to be significantly hydrophobic (hydrocarbon) to allow penetration of the cleaning composition into the resin. The compositions shown here represent a key condition that is necessary to affect proper performance. Elevated temperatures were found necessary to adequately remove the rubber-like isoprene photoresist from the inorganic substrate in 60 seconds.

What is claimed is:

1. A composition comprising:
at least one solvent;
at least one amine;
at least one sulfonated polymer; and
at least one monomer that is a mono-amide or a diamide, alone or further in combination with a diester,
wherein the at least one solvent comprises at least one ethylene glycol moiety or at least one propylene glycol moiety and wherein the length of the at least one glycol moiety or the at least one propylene glycol moiety ranges from 1 to 5 carbon atoms;
wherein at least one end group of the at least one solvent comprises ether functionality or alkyl ether functionality; and wherein the length of at least one endgroup ranges from 1 to 6 carbon atoms.

2. A composition comprising:
at least one solvent;
at least one amine; and
at least one monomer that is a mono-amide or a diamide, alone or further in combination with a diester,
wherein the at least one solvent comprises at least one ethylene glycol moiety or at least one propylene glycol moiety and wherein the length of the at least one glycol moiety or the at least one propylene glycol moiety ranges from 1 to 5 carbon atoms;
wherein at least one end group of the at least one solvent comprises ether functionality or alkyl ether functionality, and wherein the length of at least one endgroup ranges from 1 to 6 carbon atoms.

3. The composition according to claim 2, wherein the at least one solvent is at a weight percent ranging from 40% to 97%.

4. The composition according to claim 3, wherein the at least one solvent is at a weight percent ranging from 60% to 90%.

5. The composition according to claim 1, further comprising at least one additive that enhances cleaning performance.

6. The composition according to claim 2, further comprising at least one additive that enhances cleaning performance.

7. The composition according to claim 6, wherein the at least one solvent is at a weight percent ranging from 30% to 95%, the at least one monomer is at a weight percent ranging from 0.1 to 99.5%, and the at least one additive is at a weight percent ranging from 2% to 60%.

8. The composition according to claim 6, wherein the at least one additive is at least one of tetra-alkyl ammonium hydroxide or mixed alkyl/aryl ammonium hydroxide.

9. The composition according to claim 8, wherein the at least one additive is at least one of tetramethylammonium hydroxide, tetraethylammonium hydroxide, benzyltrimethylammonium hydroxide, triethylene tetramine, monoethanolamine, monoisopropanolamine, diglycolamine, 1,2-diaminoethane, 1,3-diaminomethylbenzene, 1,3-diaminomethylcyclohexane, potassium tertiary butyl hydroxide, and mixtures thereof.

10. The composition according to claim 6, wherein the at least one additive is at least one of methanesulfonic, p-toluenesulfonic, dodecylbenzene sulfonic acid, formic acid, sulfuric acid, nitric acid, phosphoric acid, and mixtures thereof.

11. The composition according to claim 6, further comprising at least one inhibitor or surfactant.

12. A method for removing at least one substance from at least one substrate comprising:
(d) coating a substance with a composition comprising:
iv. at least one solvent;
v. at least one amine;
vi. at least one water soluble, water dispersible, or water dissipatable polymer; and
vii. at least one monomer that is a mono-amide or a diamide, alone or further in combination with a diester,
(e) heating a substrate to a temperature and for a time sufficient to achieve removal of the substance, and
(f) rinsing the substrate with a volume of a rinsing agent sufficient to remove the composition and the substance.

13. A method for removing at least one substance from at least one substrate comprising,
(a) coating a substance with a composition comprising:
i. at least one solvent;
ii. at least one amine; and
iii. at least one monomer that is a mono-amide or a diamide, alone or further in combination with a diester,
(b) heating a substrate to a temperature and for a time sufficient to achieve removal of the substance, and
(c) rinsing the substrate with a volume of a rinsing agent sufficient to remove the composition and the substance.

14. The method according to claim 13, wherein the composition further comprises at least one additive that enhances cleaning performance.

15. The method according to claim 14, wherein the at least one solvent is at a weight percent ranging from 30% to 95%, the at least one monomer is at a weight percent ranging from 0.1% to 99.5%, and the at least one additive is at a weight percent ranging from 2% to 60%.

16. The method according to claim 10, wherein the at least one solvent comprises:
at least one ethylene glycol moiety or at least one propylene glycol moiety, and wherein the length of the at least one glycol moiety or the at least one propylene glycol moiety ranges from 1 to 5 carbon atoms;
wherein at least one end group of the at least one solvent comprises ether functionality or alkyl ether functionality, and wherein the length of at least one endgroup ranges from 1 to 6 carbon atoms.

17. The method according to claim 12, wherein the at least one water soluble, water dispersible, or water dissipatable polymer is selected from the group consisting of alcohol ethoxylates, bisphenol ethoxylates, bisphenol propoxylates, alkylbenzenesulfonic acid salts, cellulose acetate phthalate, cellulosic derivatives of alkoxyethyl, cellulosic derivatives of hydroxypropyl, copolymers of ethylene, copolymers of propylene oxide, dendritic polyesters, ethoxylated amines, ethoxylated alcohol salts, ethylene acrylic acid, hydroxy-methacrylates, phosphate esters, polyethylene glycols, polyethylene imine, polyethylene oxides, polyvinyl alcohol, polyvinyl pyrollidinone, starch, styrene maleic anhydride, sulfonated acrylics, sulfonated polystyrenes, sulfopolyester, rosin acids, and mixtures thereof.

18. The method according to claim 17, wherein the at least one water soluble, water dispersible, or water dissipatable polymer is at least one sulfonated polymer.

19. The method according to claim 13, wherein the at least one additive is at least one of tetraalkyl ammonium hydroxide and mixed alkyl/aryl ammonium hydroxide.

20. The method according to claim 19, wherein the at least one additive is at least one of tetramethylammonium hydroxide, tetraethylammonium hydroxide, enzyltrimethylammonium hydroxide, triethylene tetramine, monoethanolamine, monoisopropanolamine, diglycolamine, 1,2-diaminoethane, 1,3-diaminomethylbenzene, 1,3-diaminomethylcyclohexane, potassium tertiary butyl hydroxide, and mixtures thereof.

21. The method according to claim 14, wherein the at least one additive is at least one of methanesulfonic, p-toluenesulfonic, dodecylbenzene sulfonic acid, formic acid, sulfuric acid, nitric acid, phosphoric acid, and mixtures thereof.

22. The method according to claim 13, further comprising at least one inhibitor or surfactant.

23. The method according to claim 13, wherein the substrate is heated to a temperature ranging from 25° C. to 400° C.

24. The method according to claim 13, wherein the temperature of the rinsing agent ranges from 5° C. and 100° C.

25. The method according to claim 13, wherein the at least one substance comprises at least one positive-tone photoresist or at least one negative-tone photoresist.

26. The method according to claim 13, wherein the at least one substrate comprises a semiconductive wafer, a flat panel display, or a printed circuit board.

27. The method according to claim 13, wherein said coating comprises spray coating, spin coating, or slit coating.

28. The method according to claim 13, wherein the rinsing agent is water, acetone, isopropyl alcohol, or mixtures thereof.

29. A composition produced by combining:
at least one solvent at a weight percent ranging from 0.5% to 99.5%;
at least one amine; and
at least one sulfonated polymer at weight percent ranging from 0.5 to 99.5%.

30. A composition produced by combining:
at least one solvent at a weight percent ranging from 0.5% to 99.5%;
at least one amine; and
at least one sulfonated monomer at weight percent ranging from 0.1% to 99.5%.
